(19) United States
(12) Patent Application Publication
(10) Pub. No.: US 2014/0084274 A1
(43) Pub. Date: Mar. 27, 2014

(54) Light-Emitting Element

(71) Applicant: Semiconductor Energy Laboratory Co., Ltd., Kanagawa-ken (JP)

(72) Inventors: Shunpei Yamazaki, Tokyo (JP); Satoshi Seo, Sagamihara (JP); Satoko Shitagaki, Isehara (JP); Nobuharu Ohsawa, Zama (JP); Hideko Inoue, Atsugi (JP); Hiroshi Kadoma, Sagamihara (JP); Harue Osaka, Atsugi (JP)

(73) Assignee: Semiconductor Energy Laboratory Co., Ltd., Kanagawa-ken (JP)

(21) Appl. No.: 14/030,554

(22) Filed: Sep. 18, 2013

(30) Foreign Application Priority Data
Sep. 21, 2012 (JP) 2012-208661

(51) Int. Cl. H01L 51/50

(52) U.S. Cl. CPC H01L 51/5004; H01L 51/5016
USPC 257/40

(57) ABSTRACT

A light-emitting element with high emission efficiency is provided. The light-emitting element includes, between a pair of electrodes, a layer containing a p-type host, a light-emitting layer containing a guest, the p-type host, and an n-type host, and a layer containing the n-type host. A combination of the p-type host and the n-type host forms an exciplex. Among the layer containing the p-type host, the light-emitting layer, and the layer containing the n-type host, the light-emitting layer has the highest secondary ion intensity of the n-type host, the layer containing the n-type host has the second-highest secondary ion intensity of the n-type host, and the layer containing the p-type host has the lowest secondary ion intensity of the n-type host in analysis by a time-of-flight secondary ion mass spectrometer.

### BACKGROUND OF THE INVENTION

1. Field of the Invention

The present invention relates to light-emitting elements using an organic electroluminescence (EL) phenomenon (hereinafter such light-emitting elements are also referred to as organic EL elements).

2. Description of the Related Art

Organic EL elements have been actively researched and developed. In a fundamental structure of the organic EL element, a layer (hereinafter also referred to as a light-emitting layer) containing an organic compound that is a light-emitting substance is provided between a pair of electrodes. The organic EL element has attracted attention as a next-generation flat panel display element owing to characteristics such as feasibility of being thinner and lighter, high speed response to input signals, and capability of direct current low voltage driving. In addition, a display using such an organic EL element has a feature that it is excellent in contrast and image quality, and has a wide viewing angle. Further, being a planar light source, the organic EL element has been attempted to be applied as a light source such as a backlight of a liquid crystal display and a lighting device.

The emission mechanism of the organic EL element is of a carrier-injection type. That is, by voltage application to the element, electrons and holes are respectively injected from a cathode and an anode to the light-emitting layer; accordingly, current flows. The injected electrons and holes then lead the organic compound that is a light-emitting substance to its excited state, so that light emission is obtained from the excited organic compound.

The excited state of an organic compound can be a singlet excited state or a triplet excited state. Light emission from the singlet excited state (S*) is called fluorescence, and light emission from the triplet excited state (T*) is called phosphorescence. Here, in a compound emitting fluorescence (hereinafter also referred to as a fluorescent compound), in general, phosphorescence is not observed at room temperature, and only fluorescence is observed. Accordingly, the internal quantum efficiency (the ratio of generated photons to injected carriers) in a light-emitting element including a fluorescent compound is assumed to have a theoretical limit of 25% on the basis of the ratio of the singlet excited state to the triplet excited state.

On the other hand, when a compound emitting phosphorescence (hereinafter also referred to as a phosphorescent compound) is used, the internal quantum efficiency can be theoretically increased to 100%. That is, higher emission efficiency can be obtained than using a fluorescent compound. For these reasons, a light-emitting element including a phosphorescent compound has been actively developed in recent years in order to obtain a light-emitting element with high emission efficiency.

As the phosphorescent compound, an organometallic complex that has iridium or the like as a central metal has particularly attracted attention because of its high phosphorescence quantum yield; for example, an organometallic complex that has iridium as a central metal is disclosed as a phosphorescent material in Patent Document 1.

When a light-emitting layer of a light-emitting element is formed using a phosphorescent compound described above, in order to suppress concentration quenching or quenching due to triplet-triplet annihilation in the phosphorescent compound, the light-emitting layer is often formed such that the phosphorescent compound is dispersed in a matrix of another compound. Here, the compound serving as the matrix is called a host, and the compound dispersed in the matrix, such as a phosphorescent compound, is called a guest.

General elementary processes for light emission in a light-emitting element (hereinafter also referred to as a phosphorescent light-emitting element) using a phosphorescent compound as a guest will be described below.

(1) Direct Recombination Process

In the case where an electron and a hole recombine in a guest molecule and the guest molecule is brought into an excited state, the guest molecule acts as follows: when the excited state is a triplet excited state, the guest molecule emits phosphorescence and when the excited state is a singlet excited state, the guest molecule undergoes intersystem crossing to a triplet excited state and emits phosphorescence.

In other words, in the direct recombination process, as long as the efficiency of intersystem crossing and the phosphorescence quantum yield of the guest molecule are high, high emission efficiency can be obtained.

(2) Energy Transfer Process

(2-1) The Case where an Electron and a Hole Recombine in a Host Molecule and the Host Molecule is Brought into a Triplet Excited State

When the triplet excitation energy level (T₁ level) of the host molecule is higher than that of the guest molecule, excitation energy is transferred from the host molecule to the guest molecule, and thus the guest molecule is brought into a triplet excited state. The guest molecule in the triplet excited state emits phosphorescence.

(2-2) The Case where an Electron and a Hole Recombine in a Host Molecule and the Host Molecule is Brought into a Singlet Excited State

When a singlet excitation energy level (S₁ level) of the host molecule is higher than the S₁ level and T₁ level of the guest molecule, excitation energy is transferred from the host molecule to the guest molecule, and thus, the guest molecule is brought into a singlet excited state or a triplet excited state. The guest molecule in the triplet excited state emits phosphorescence. In addition, the guest molecule in the singlet excited state undergoes intersystem crossing to a triplet excited state, and emits phosphorescence.

In other words, in the energy transfer process, it is important how efficiently both the triplet excitation energy and the singlet excitation energy of the host molecule can transfer to the guest molecule.

In view of the above-described energy transfer processes, a reduction in emission efficiency is caused in the case where the host molecule itself is deactivated by emitting the excitation energy as light or heat before the excitation energy of the host molecule is transferred to the guest molecule.

### REFERENCE

### Patent Document

[Patent Document 1] International Publication WO 00/70655 pamphlet
[Patent Document 2] Japanese Published Patent Application No. 2002-313583

Here, when the host molecule is in a singlet excited state (the above (2-2)), the energy is unlikely to transfer to the guest molecule, i.e., the phosphorescent compound, and the emission efficiency is likely to decrease as compared to when the host molecule is in a triplet excited state (the above (2-1)). The reason is found in consideration of an energy transfer process.

In consideration of Förster mechanism (dipole-dipole interaction) and Dexter mechanism (electron exchange interaction), which are known as mechanisms of energy transfer between molecules, it is preferable that, for improvement of efficiency of energy transfer from a host to a guest (for fabrication of a light-emitting element with high emission efficiency), an emission spectrum of the host (a fluorescence spectrum in energy transfer from a singlet excited state, and a phosphorescence spectrum in energy transfer from a triplet excited state) have a large overlap with an absorption spectrum of the guest (an energy difference between a triplet excited state and a ground state in the usual case of phosphorescence). Furthermore, the T₁ level of the host should be higher than that of the guest to suppress the reverse energy transfer from the T₁ level of the guest to the T₁ level of the host.

An organometallic complex (e.g., an organometallic iridium complex) can be given as an example of a phosphorescent compound which can be used as a guest in a phosphorescent light-emitting element. Organometallic complexes generally have an absorption band originating from the triplet metal-to-ligand charge transfer (MLCT) transition in a relatively long wavelength region. Their excitation spectra suggest that this absorption band in a long wavelength region (mainly located around 500 nm to 600 nm) greatly contributes to the emission. Hence, it is preferable that this absorption band in a long wavelength region have a large overlap with the phosphorescence spectrum of the host. This is because such a large overlap allows efficient energy transfer from the triplet excited state of the host, resulting in an efficient formation of the triplet excited state of the guest.

On the other hand, the fluorescence spectrum corresponding to the S₁ level is observed in a considerably short wavelength region compared with the phosphorescence spectrum corresponding to the T₁ level because the S₁ level of the host is higher than the T₁ level. This means that the overlap of the fluorescence spectrum of the host with the absorption band (originating from the triplet MLCT transition) in a long wavelength region of the guest is small. Therefore, it is impossible to sufficiently utilize the energy transfer from the singlet excited state of the host to the guest.

That is, in the conventional phosphorescent light-emitting elements, there is a quite low probability that the energy transfer from the singlet excited state of the host to the guest occurs to form the singlet excited state of the guest, which is subsequently transformed to the triplet excited state by the intersystem crossing.

It is known that in the case where a light-emitting element has a junction of different layers, an energy gap generated at the interface causes an increase in drive voltage and a decrease in power efficiency (see Patent Document 2).

The present invention is made in view of these problems. An object of one embodiment of the present invention is to provide a light-emitting element with high emission efficiency.

### SUMMARY OF THE INVENTION

A light-emitting element of one embodiment of the present invention includes a first electrode, a light-emitting layer over the first electrode, a first layer over the light-emitting layer, and a second electrode over the first layer. The light-emitting layer contains a phosphorescent compound (also referred to as a guest) and an organic compound, where the content of the organic compound is higher than that of the phosphorescent compound. The first layer contains the organic compound. Secondary ion intensity of the organic compound is higher in the light-emitting layer than in the first layer in analysis by a time-of-flight secondary ion mass spectrometer (ToF-SIMS).

A light-emitting element of another embodiment of the present invention includes a first electrode, a first layer over the first electrode, a light-emitting layer over the first layer, a second layer over the light-emitting layer, and a second electrode over the second layer. The light-emitting layer contains a phosphorescent compound, a first organic compound, and a second organic compound, where the content of the second organic compound is the highest. The first layer contains the first organic compound. The second layer contains the second organic compound. A combination of the first organic compound and the second organic compound forms an exciplex. Among the first layer, the light-emitting layer, and the second layer, the light-emitting layer shows the highest secondary ion intensity of the second organic compound, the second layer shows the second-highest secondary ion intensity of the second organic compound, and the first layer shows the lowest secondary ion intensity of the second organic compound in analysis by a ToF-SIMS.

A light-emitting element of another embodiment of the present invention includes a first electrode, a first layer over the first electrode, a light-emitting layer over the first layer, a second layer over the light-emitting layer, and a second electrode over the second layer. The light-emitting layer contains a phosphorescent compound, a first organic compound with a hole-transport property, and a second organic compound with an electron-transport property. The first layer contains the first organic compound. The second layer contains the second organic compound. A combination of the first organic compound and the second organic compound forms an exciplex. Among the first layer, the light-emitting layer, and the second layer, the light-emitting layer has the highest secondary ion intensity of the second organic compound, the second layer has the second-highest secondary ion intensity of the second organic compound, and the first layer has the lowest secondary ion intensity of the second organic compound in analysis by a ToF-SIMS.

In the light-emitting element of one embodiment of the present invention, it is preferable that among the first layer, the light-emitting layer, and the second layer, the second layer has the lowest secondary ion intensity of the first organic compound in the analysis by the ToF-SIMS.

In this specification, in view of the hole-transport property and the electron-transport property of the first organic compound and the second organic compound, the organic compound with a hole-transport property is also referred to as a p-type host, and the organic compound with an electron-transport property is also referred to as an n-type host.

In the above light-emitting element, the phosphorescent compound is excited through energy transfer from the exciplex to the phosphorescent compound, so that light emission is obtained from the excited state of the phosphorescent compound. Note that a layer other than the light-emitting layer may be capable of emitting light in response to electric current injection.

An exciplex probably has an extremely small difference between the singlet excitation energy and the triplet excitation energy. In other words, the emission from the singlet state of the exciplex and that from the triplet state of the exciplex appear in wavelength regions which are very close to each other. In addition, because emission of an exciplex is usually observed on the longer wavelength side than that of its monomer state, the overlap between the absorptions of phosphorescent compounds, which appear in a long wavelength region and originate from the triplet MLCT transition, and the emission of the exciplex can be large. This means that energy can be efficiently transferred from both of the singlet and triplet states of the exciplex to the phosphorescent compounds, which contributes to the improvement in the emission efficiency of the light-emitting elements.

Moreover, an exciplex does not possess a ground state. Thus, there is no process of the reverse energy transfer from the triplet excited state of the phosphorescent compound to the exciplex, and a reduction in emission efficiency of the light-emitting element caused by this process can be ignored.

Further, an appropriate combination of a p-type host and an n-type host forms an exciplex when the p-type host and/or the n-type host are/is put in an excited state. Note that a necessary condition for the exciplex formation is that the HOMO level of the n-type host<the HOMO level of the p-type host<the LUMO level of the n-type host<the LUMO level of the p-type host, but this is not a sufficient condition. For example, a combination of NPB as a p-type host and Alq₃ as an n-type host satisfies the above condition but does not form an exciplex.

In the case where a p-type host and an n-type host can form an exciplex, as described above, a phosphorescent compound can be excited as a result of energy transfer from both the singlet state and the triplet state of the exciplex to the phosphorescent compound, so that emission efficiency can be higher than that of the conventional phosphorescent light-emitting element.

In addition, the light-emitting element is preferable in that a junction of dissimilar materials is reduced and as a result, an increase in drive voltage or a reduction in power efficiency due to an energy gap generated at an interface can be suppressed.

In the light-emitting element of one embodiment of the present invention, the interface between the light-emitting layer and the second layer serves as an obstacle to holes, but hardly serves as an obstacle to electrons. The interface between the light-emitting layer and the first layer serves as an obstacle to electrons, but hardly serves as an obstacle to holes. Therefore, electrons and holes are confined in the light-emitting layer or between the first layer and the second layer. As a result, electrons and holes can be prevented from reaching an anode and a cathode, respectively, whereby a reduction in emission efficiency can be suppressed.

In general, an exciplex provides a broad emission spectrum; however, in one embodiment of the present invention, an emission spectrum with a small half width can be obtained since the phosphorescent compound emits light, and as a result, a light-emitting element emitting light with excellent color purity can be obtained.

In the light-emitting element of one embodiment of the present invention, the light-emitting layer contains the phosphorescent compound, the first organic compound, and the second organic compound, where the content of the second organic compound is the highest. Among the first layer, the light-emitting layer, and the second layer included in the light-emitting element of one embodiment of the present invention, the second layer has the highest content (volume fraction or molar fraction) of the second organic compound, and the light-emitting layer has the second-highest content (volume fraction or molar fraction) of the second organic compound. However, analysis of the light-emitting element of one embodiment of the present invention by a ToF-SIMS shows that the second organic compound contained in the light-emitting layer has secondary ion intensity which is relatively high despite the low content. As described above, among the first layer, the light-emitting layer, and the second layer included in the light-emitting element of one embodiment of the present invention, the light-emitting layer has the highest secondary ion intensity of the second organic compound and the second layer has the second-highest secondary ion intensity of the second organic compound.

In analysis by a ToF-SIMS, it can be said that when a material contained in a layer has high secondary ion intensity, the molecules of the material are not readily decomposed at the time of ionization. It is thus suggested that even in the case where current flows into the light-emitting element of one embodiment of the present invention, the molecules of the second organic compound contained in the light-emitting layer are less likely to be decomposed than the molecules of the second organic compound existing alone. Therefore, by application of one embodiment of the present invention, a light-emitting element with a long lifetime can be obtained.

A light-emitting element of another embodiment of the present invention includes a guest, a p-type host, and an n-type host in a light-emitting layer. Among a first layer, the light-emitting layer, and a second layer included in the light-emitting element of one embodiment of the present invention, the second layer has the highest content (volume fraction or molar fraction) of the n-type host, and the light-emitting layer has the second-highest content (volume fraction or molar fraction) of the n-type host. However, analysis of the light-emitting element of one embodiment of the present invention by a ToF-SIMS shows that the n-type host contained in the light-emitting layer has secondary ion intensity which is relatively high despite the low content. As described above, among the first layer, the light-emitting layer, and the second layer included in the light-emitting element of one embodiment of the present invention, the light-emitting layer has the highest secondary ion intensity of the n-type host and the second layer has the second-highest secondary ion intensity of the n-type host. It is thus suggested that even in the case where current flows into the light-emitting element of one embodiment of the present invention, the molecules of the n-type host contained in the light-emitting layer are less likely to be decomposed than the molecules of the n-type host existing alone. Therefore, by application of one embodiment of the present invention, a light-emitting element with a long lifetime can be obtained.

Specifically, an aromatic amine compound is preferably used as the p-type host. A nitrogen-containing heteroaromatic compound is preferably used as the n-type host. A six-membered heteroaromatic compound is preferably used as the n-type host. In particular, the n-type host preferably includes a diazine ring.

Either the p-type host or the n-type host may be a fluorescent material. The concentrations of the p-type host and the n-type host in the light-emitting layer are each preferably 10% or more.

In the aforementioned light-emitting element, it is preferable that the phosphorescent compound be an organometallic complex. The phosphorescent compound may be contained in the first layer, the second layer, a region between the light-emitting layer and the first layer, or a region between the light-emitting layer and the second layer, besides the light-emitting layer.

In one embodiment of the present invention, the light-emitting layer contains the p-type host molecules, the n-type host molecules, and the guest molecules.

Needless to say, the molecules are not necessarily arranged regularly and may be arranged in an almost irregular manner. In particular, when the light-emitting layer is formed as a thin film with a thickness of 50 nm or less, it is preferably amorphous, and thus a combination of materials that are hardly crystallized is preferable. The layer containing the p-type host and the layer containing the n-type host may contain two or more different kinds of compounds.

The light-emitting element of one embodiment of the present invention can be applied to a light-emitting device, an electronic device, and a lighting device. The light-emitting element of one embodiment of the present invention has high emission efficiency and thus allows fabrication of a light-emitting device, an electronic device, and a lighting device which have low power consumption.

The light-emitting element of one embodiment of the present invention includes the layer containing the p-type host, the light-emitting layer containing the guest, the p-type host, and the n-type host, and the layer containing the n-type host. Since the combination of the p-type host and the n-type host forms an exciplex, one embodiment of the present invention not only enables confinement of carriers and a reduction in a barrier to carrier injection into the light-emitting layer but also allows formation of an exciplex and the utilization of the energy transfer process from both of the singlet and triplet excited states of the exciplex; thus, a light-emitting element with high emission efficiency can be obtained.

### BRIEF DESCRIPTION OF THE DRAWINGS

FIGS. 1A to 1I are schematic diagrams of embodiments of the present invention.

FIGS. 2A to 2D illustrate principles of embodiments of the present invention.

FIGS. 3A to 3D each illustrate an example of a light-emitting element.

FIGS. 4A to 4C illustrate examples of an apparatus for manufacturing a light-emitting element.

FIGS. 5A and 5B illustrate an example of a light-emitting device.

FIGS. 6A and 6B illustrate an example of a light-emitting device.

FIGS. 7A to 7E illustrate examples of electronic devices.

FIGS. 8A and 8B illustrate examples of lighting devices.

FIG. 9 is a graph showing an absorption spectrum and photoluminescence spectra in Example 1.

FIG. 10 is a graph showing an absorption spectrum and photoluminescence spectra in Example 1.

FIG. 11 illustrates a light-emitting element in Example.

FIG. 12 is a graph showing current density-luminance characteristics of a light-emitting element in Example 2.

FIG. 13 is a graph showing voltage-luminance characteristics of the light-emitting element in Example 2.

FIG. 14 is a graph showing luminance-current efficiency characteristics of the light-emitting element in Example 2.

FIG. 15 is a graph showing luminance-external quantum efficiency characteristics of the light-emitting element in Example 2.

FIG. 16 is a graph showing an emission spectrum of the light-emitting element in Example 2.

FIGS. 17A and 17B are graphs showing measurement results of the light-emitting element in Example 2 by a ToF-SIMS.

FIG. 18 is a graph showing current density-luminance characteristics of a light-emitting element in Example 3.

FIG. 19 is a graph showing voltage-luminance characteristics of the light-emitting element in Example 3.

FIG. 20 is a graph showing luminance-current efficiency characteristics of the light-emitting element in Example 3.

FIG. 21 is a graph showing luminance-external quantum efficiency characteristics of the light-emitting element in Example 3.

FIG. 22 is a graph showing an emission spectrum of the light-emitting element in Example 3.

FIGS. 23A and 23B are graphs showing measurement results of the light-emitting element in Example 3 by a ToF-SIMS.

FIG. 24 is a graph showing results of a reliability test of the light-emitting element in Example 3.

### DETAILED DESCRIPTION OF THE INVENTION

Embodiments will be described in detail with reference to drawings. Note that the present invention is not limited to the following description, and it will be easily understood by those skilled in the art that various changes and modifications can be made without departing from the spirit and scope of the invention. Therefore, the invention should not be construed as being limited to the description in the following embodiments. Note that in the structures of the invention described below, the same portions or portions having similar functions are denoted by the same reference numerals in different drawings, and description of such portions is not repeated.

### Embodiment 1

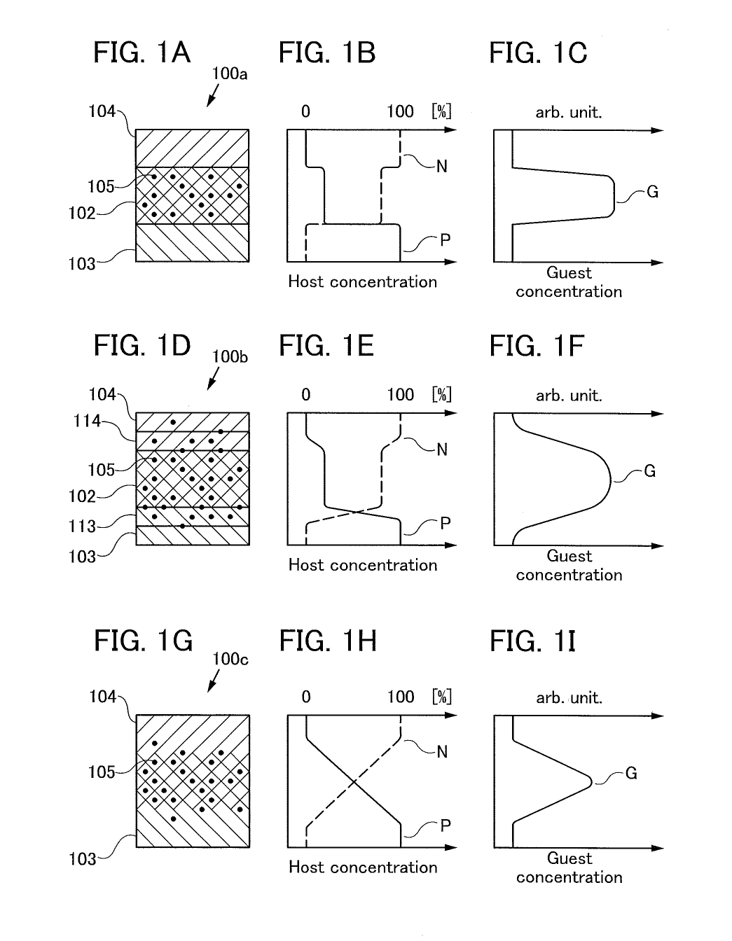

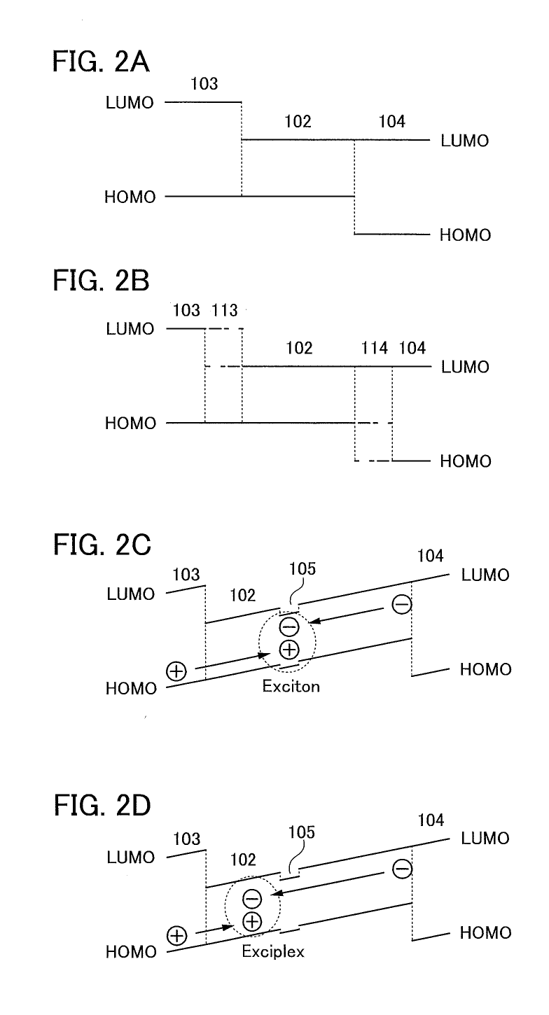

In this embodiment, a light-emitting element of one embodiment of the present invention will be described with reference to FIGS. 1A to 1I and FIGS. 2A to 2D.

A light-emitting element of one embodiment of the present invention includes a layer (an EL layer) containing a light-emitting organic compound between a pair of electrodes (a first electrode and a second electrode). One of the pair of electrodes functions as an anode and the other functions as a cathode. The EL layer includes a first layer over the first electrode, a light-emitting layer over the first layer, and a second layer over the light-emitting layer. The light-emitting layer contains a phosphorescent compound (a guest), a first organic compound, and a second organic compound, where the content of the second organic compound is the highest. The first layer contains the first organic compound and does not contain the second organic compound. The second layer contains the second organic compound and does not contain the first organic compound. One of the first organic compound and the second organic compound is an organic compound with a hole-transport property (a p-type host) and the other is an organic compound with an electron-transport property (an n-type host). A combination of the p-type host and the n-type host forms an exciplex.

Among the first layer, the light-emitting layer, and the second layer included in the light-emitting element of one embodiment of the present invention, the first layer has the highest content (volume fraction or molar fraction) of the first organic compound, the light-emitting layer has the second-highest content (volume fraction or molar fraction) of the first organic compound, and the second layer does not contain the first organic compound. The second layer has the highest content (volume fraction or molar fraction) of the second organic compound, the light-emitting layer has the second-highest content (volume fraction or molar fraction) of the second organic compound, and the first layer does not contain the second organic compound. However, analysis of the light-emitting element of one embodiment of the present invention by a ToF-SIMS shows that the first organic compound and the second organic compound contained in the light-emitting layer each have secondary ion intensity which is relatively high despite the low content.

The EL layer may further include one or more layers containing any of a substance with a high hole-injection property, a substance with a high hole-transport property, a substance with a high electron-transport property, a substance with a high electron-injection property, a substance with a bipolar property (a substance with a high electron-transport property and a high hole-transport property), and the like.

Either a low molecular compound or a high molecular compound can be used for the EL layer, and an inorganic compound may also be used.

FIG. 1A illustrates an example of a stack provided in the EL layer. A stack 100a illustrated in FIG. 1A includes, from the anode side, a layer 103 containing a p-type host, a light-emitting layer 102, and a layer 104 containing an n-type host.

The light-emitting layer 102 contains a guest 105, the p-type host, and the n-type host. In this embodiment, the guest 105 is a phosphorescent compound and is dispersed in the light-emitting layer 102. Here, the p-type host is an organic compound with a hole-transport property, and the n-type host is an organic compound with an electron-transport property. A combination of the p-type host and the n-type host forms an exciplex.

The layer 103 containing the p-type host contains a p-type host and does not contain an n-type host (which means that, in this specification, the concentration of an n-type host is 0.1% or less).

The layer 104 containing the n-type host contains an n-type host and does not contain a p-type host (which means that, in this specification, the concentration of a p-type host is 0.1% or less).

FIG. 1B illustrates distributions of the concentration of the p-type host (denoted by “P” in the diagram) and the concentration of the n-type host (denoted by “N” in the diagram) in the stack 100a illustrated in FIG. 1A. In the light-emitting layer 102 in FIG. 1B, the concentration of the p-type host is 20% and the concentration of the n-type host is 80%. The concentrations of the p-type host and the n-type host in the light-emitting layer may be appropriately determined in consideration of the transport properties of the p-type host and the n-type host, or the like, but it is preferable that the concentrations of the p-type host and the n-type host be each 10% or more.

In the layer 103 containing the p-type host, the concentration of the n-type host is extremely low and is 0.1% or less as described above. In a similar manner, in the layer 104 containing the n-type host, the concentration of the p-type host is extremely low and is 0.1% or less. Of course, it is not necessary that the concentrations change drastically at the interface between the light-emitting layer 102 and the layer 103 containing the p-type host and at the interface between the light-emitting layer 102 and the layer 104 containing the n-type host.

FIG. 1C illustrates a distribution of the concentration of the guest 105 (denoted by “G” in the diagram) in the stack 100a illustrated in FIG. 1A. The guest 105 is dispersed in only the light-emitting layer 102 in FIG. 1C, but may be contained in part of the layer 103 containing the p-type host or part of the layer 104 containing the n-type host.

FIG. 1D illustrates another example of a stack provided in the EL layer. A stack 100b illustrated in FIG. 1D includes, from the anode side, the layer 103 containing the p-type host, the light-emitting layer 102, and the layer 104 containing the n-type host. Further, a p-type transition region 113 in which the concentrations of the p-type host and the n-type host continuously change is provided between the light-emitting layer 102 and the layer 103 containing the p-type host, and an n-type transition region 114 in which the concentrations of the p-type host and the n-type host continuously change is provided between the light-emitting layer 102 and the layer 104 containing the n-type host.

Note that in one embodiment of the present invention, the EL layer may include only one of the p-type transition region 113 and the n-type transition region 114. Further, the p-type transition region 113 and the n-type transition region 114 may be capable of emitting light and may be included in the light-emitting layer 102. The p-type transition region 113 and the n-type transition region 114 each preferably has a thickness greater than or equal to 1 nm and less than or equal to 50 nm.

FIG. 1E illustrates distributions of the concentration of the p-type host and the concentration of the n-type host in the stack 100b illustrated in FIG. 1D. As illustrated in FIG. 1E, the concentration of the p-type host and the concentration of the n-type host continuously change in the p-type transition region 113 and the n-type transition region 114.

FIG. 1F illustrates a distribution of the concentration of the guest 105 in the stack 100b illustrated in FIG. 1D. As illustrated in FIG. 1F, the guest 105, which is contained in the light-emitting layer 102, may be also contained in the p-type transition region 113 or the n-type transition region 114, and moreover, may be also contained in part of the layer 103 containing the p-type host or part of the layer 104 containing the n-type host.

FIG. 1G illustrates another example of a stack provided in the EL layer. FIG. 1H illustrates distributions of the concentration of the p-type host and the concentration of the n-type host in a stack 100c illustrated in FIG. 1G. As illustrated in FIG. 1H, the concentrations of the p-type host and the n-type host continuously change in a region between the layer 103 containing the p-type host and the layer 104 containing the n-type host in the stack 100c. A light-emitting layer in this specification is, in a broad sense, a region in the above region which contains the guest 105, the p-type host, and the n-type host and in which the concentrations of the p-type host and the n-type host are each 10% or more.

FIG. 1I illustrates a distribution of the concentration of the guest 105 in the stack 100c illustrated in FIG. 1G. The guest 105 is contained in the light-emitting layer in the above broad sense as illustrated in FIG. 1I. Note that although this embodiment describes a structure in which the light-emitting layer 102 is formed over the layer 103 containing the p-type host and the layer 104 containing the n-type host is formed over the light-emitting layer 102, a reverse structure, in which the layer 103 containing the p-type host is formed over the layer 104 containing the n-type host with the light-emitting layer 102 provided therebetween, is also one embodiment of the present invention.

Energy levels of the stack 100a illustrated in FIG. 1A will be described with reference to FIG. 2A. The HOMO levels and the LUMO levels of the p-type host and the n-type host which are used for the stack 100a have the following relationship: the HOMO level of the n-type host<the HOMO level of the p-type host<the LUMO level of the n-type host<the LUMO level of the p-type host.

In the light-emitting layer 102 in which the p-type host and the n-type host are mixed, it can be recognized, from a viewpoint of carrier transfer, that the HOMO level is equal to the HOMO level of the p-type host and the LUMO level is equal to the LUMO level of the n-type host because holes and electrons are transferred using the HOMO level of the p-type host and the LUMO level of the n-type host, respectively. As a result, at the interface between the light-emitting layer 102 and the layer 103 containing the p-type host, there is a gap between the LUMO levels, which serves as a barrier to electron transfer. Similarly, at the interface between the light-emitting layer 102 and the layer 104 containing the n-type host, there is a gap between the HOMO levels, which serves as a barrier to hole transfer.

On the other hand, at the interface between the light-emitting layer 102 and the layer 103 containing the p-type host, the HOMO levels are equal and thus there is no barrier to hole transfer, and similarly at the interface between the light-emitting layer 102 and the layer 104 containing the n-type host, the LUMO levels are equal and thus there is no barrier to electron transfer.

As a result, electrons are easily transferred from the layer 104 containing the n-type host to the light-emitting layer 102, but the gap between the LUMO levels of the light-emitting layer 102 and the layer 103 containing the p-type host hinders electron transfer from the light-emitting layer 102 to the layer 103 containing the p-type host.

Similarly, holes are easily transferred from the layer 103 containing the p-type host to the light-emitting layer 102, but the gap between the HOMO levels of the light-emitting layer 102 and the layer 104 containing the n-type host hinders hole transfer from the light-emitting layer 102 to the layer 104 containing the n-type host. As a result, electrons and holes can be confined in the light-emitting layer 102.

Energy levels of the stack 100b illustrated in FIG. 1B will be described with reference to FIG. 2B. The HOMO levels and the LUMO levels of the light-emitting layer 102, the layer 103 containing the p-type host, and the layer 104 containing the n-type host are similar to those illustrated in FIG. 2A.

As described above, the concentration of the p-type host and the concentration of the n-type host continuously change in the p-type transition region 113 and the n-type transition region 114. However, unlike the case where the conduction band and the valence band of an inorganic semiconductor material change continuously with a change in composition, the LUMO level and the HOMO level of a mixed organic compound hardly change continuously. This is because the electrical conduction of an organic compound is hopping conduction, which is different from the electrical conduction of an inorganic semiconductor.

For example, as the concentration of the n-type host decreases and the concentration of the p-type host increases, electrons become less likely to be conducted, which is understood to be not because the LUMO level rises continuously but because the probability of transfer decreases due to an increase in distance between the n-type host molecules and because additional energy is necessary for hopping to a LUMO level of the neighboring p-type host that has a higher LUMO level.

Therefore, in the n-type transition region 114, the HOMO is in a mixed state of the HOMOs of the n-type host and the p-type host, and specifically, the HOMO is highly likely to be the HOMO of the p-type host in a portion close to the light-emitting layer 102 and is more likely to be the HOMO of the n-type host in a portion closer to the layer 104 containing the n-type host. The same applies to the p-type transition region.

However, even in the presence of the p-type transition region 113 and the n-type transition region 114 as described above, at the interface between the light-emitting layer 102 and the layer 103 containing the p-type host, there is a gap between the LUMO levels, which serves as a barrier to electron transfer, and at the interface between the light-emitting layer 102 and the layer 104 containing the n-type host, there is a gap between the HOMO levels, which serves as a barrier to hole transfer. This is the same as FIG. 2A.

Note that an interface having a drastic concentration change as in FIG. 2A causes a problem in that, for example, the vicinity of the interface readily deteriorates because electrons are likely to be concentrated at the interface. In contrast, an unclear interface like that in FIG. 2B does not cause deterioration of a specific portion because electrons stay in probabilistically determined portions. In other words, it is possible to suppress deterioration of a light-emitting element, and accordingly, the reliability thereof can be increased.

On the other hand, at the interface between the light-emitting layer 102 and the p-type transition region 113 and the interface between the p-type transition region 113 and the layer 103 containing the p-type host, the HOMO levels are equal and thus there is no barrier to hole transfer, and at the interface between the light-emitting layer 102 and the n-type transition region 114 and the interface between the n-type transition region 114 and the layer 104 containing the n-type host, the LUMO levels are equal and thus there is no barrier to electron transfer.

As a result, electrons are easily transferred from the layer 104 containing the n-type host to the light-emitting layer 102, but the gap between the LUMO levels in the p-type transition region 113 hinders electron transfer from the light-emitting layer 102 to the layer 103 containing the p-type host. Similarly, holes are easily transferred from the layer 103 containing the p-type host to the light-emitting layer 102, but the gap between the HOMO levels in the n-type transition region 114 hinders hole transfer from the light-emitting layer 102 to the layer 104 containing the n-type host.

As a result, electrons and holes can be confined in the light-emitting layer 102. In the stack 100c in which the concentration of the p-type host and the concentration of the n-type host change continuously between the layer 103 containing the p-type host and the layer 104 containing the n-type host, it can be similarly considered that electrons and holes can be efficiently confined between the layer 103 containing the p-type host and the layer 104 containing the n-type host.

Next, light-emission processes for the guest 105 will be described. Here, the stack 100a is used as an example in the description; the same applies to the stack 100b and the stack 100c. As described above, general elementary processes of light emission in a light-emitting element using a phosphorescent compound as a guest include the direct recombination process and the energy transfer process.

First, the direct recombination process is described with reference to FIG. 2C. Holes are injected into the HOMO of the light-emitting layer 102 from the layer 103 which contains the p-type host and is connected to the anode, and electrons are injected into the LUMO of the light-emitting layer 102 from the layer 104 which contains the n-type host and is connected to the cathode. Because the guest 105 exists in the light-emitting layer 102, the guest can be brought into an excited state (an intramolecular exciton) by injection of holes and electrons into the HOMO and the LUMO of the guest under appropriate conditions.

However, it is technically difficult to efficiently inject holes and electrons into the HOMO and the LUMO of the guest that is thinly dispersed in the light-emitting layer 102; therefore, the probability of the process is not high enough. The efficiency can be increased by setting the LUMO level of the guest to be lower than the LUMO level of the n-type host by 0.1 eV to 0.3 eV so that the guest preferentially traps electrons. A similar effect can be obtained by setting the HOMO level of the guest to be higher than the HOMO level of the p-type host by 0.1 eV to 0.3 eV. Note that although the HOMO level of the guest is lower than that of the p-type host in FIG. 2C, electrons are efficiently trapped since the LUMO level of the guest is sufficiently lower than the LUMO level of the p-type host and the LUMO level of the n-type host.

It is not preferable to set the LUMO level of the guest to be lower than the LUMO level of the n-type host by 0.5 eV or more (or to set the HOMO level of the guest to be higher than the HOMO level of the p-type host by 0.5 eV or more) because, although the probability of trapping electrons (holes) increases, the conductivity of the light-emitting layer 102 decreases and only the guest on the cathode side (anode side) is excited locally.

Next, with reference to FIG. 2D, description is made on exciplex formation with an appropriate selection of the p-type host and the n-type host according to one embodiment of the present invention. In the case where holes and electrons are injected into the light-emitting layer 102 in the manner described above, compared with the probability that holes and electrons recombine in the guest, the probability that they recombine in the p-type host and the n-type host adjacent to each other in the light-emitting layer 102 is high. In such a case, the p-type host and the n-type host form an exciplex. Here, an exciplex will be described in detail.

An exciplex is formed by an interaction between dissimilar molecules in excited states. The exciplex is generally known to be easily formed between a material having a relatively deep (low) LUMO level (here, the n-type host) and a material having a relatively shallow (high) HOMO level (here, the p-type host).

Here, an emission wavelength of the exciplex depends on a difference in energy between the HOMO level of the p-type host and the LUMO level of the n-type host. When the energy difference is large, the emission wavelength is short. When the energy difference is small, the emission wavelength is long. When the exciplex is formed by the p-type host and the n-type host, the LUMO level and the HOMO level of the exciplex originate from the n-type host and the p-type host, respectively.

Therefore, the energy difference of the exciplex is smaller than the energy difference of the p-type host and the energy difference of the n-type host. In other words, the emission wavelength of the exciplex is longer than the emission wavelength of the p-type host and the emission wavelength of the n-type host.

The process of the exciplex formation is considered to be roughly classified into two processes.

### <<Electroplex>>

In this specification, the term “electroplex” means an exciplex which is directly formed by the p-type host in the ground state and the n-type host in the ground state.

As described above, in the energy transfer process of the general light-emission process, a hole and an electron recombine in a host (causing excitation), and excitation energy is transferred from the host in the excited state to a guest, whereby the guest is brought into an excited state to emit light.

At this time, before the excitation energy is transferred from the host to the guest, the host itself might emit light or the excitation energy might turn into thermal energy, which leads to deactivation of the excitation energy. In particular, when the host is in a singlet excited state, an excitation lifetime is shorter than that at the time when it is in a triplet excited state, which easily leads to deactivation of excitation energy. The deactivation of excitation energy is one of causes for deterioration and decrease in lifetime of a light-emitting element.

However, when an electroplex is formed by the p-type host and the n-type host having carriers (cation or anion), formation of a singlet exciton having a short excitation lifetime can be suppressed. In other words, there can be a process where an exciplex is directly formed without formation of a singlet exciton. Thus, the deactivation of singlet excitation energy of the p-type host or the n-type host can be inhibited. Accordingly, a light-emitting element having a long lifetime can be obtained.

In one embodiment of the present invention, it is possible to obtain a light-emitting element having high emission efficiency by suppressing the generation of the singlet excited state of a host and transferring energy from an electroplex formed instead to a guest, in the above-described manner.

### <<Formation of Exciplex by Exciton>>

As another process, there is thought to be an elementary process where one of the p-type host and the n-type host forms a singlet exciton and then interacts with the other in the ground state to form an exciplex. Unlike an electroplex, a singlet excited state of the p-type host or the n-type host is temporarily generated in this case, but the singlet excited state is rapidly converted into an exciplex, and thus, deactivation of singlet excitation energy can be inhibited. Thus, it is possible to inhibit deactivation of excitation energy of the host.

Note that when the difference between the HOMO levels of the p-type and n-type hosts and the difference between the LUMO levels of the p-type and n-type hosts are large (specifically, 0.3 eV or more), electrons are preferentially injected into the n-type host and holes are preferentially injected into the p-type host. In this case, it is thought that the process where an electroplex is formed takes precedence over the process where an exciplex is formed through a singlet exciton.

Note that in order to increase the efficiency of the energy transfer process, it is preferable in either Förster mechanism or Dexter mechanism that the overlap between the emission spectrum of an exciplex and the absorption spectrum of a guest be larger than the overlap between the emission spectrum of a p-type host (or an n-type host) alone and the absorption spectrum of the guest considering the importance of the absorption band originating from the MLCT transition.

In addition, in order to increase the energy transfer efficiency, it is preferable to increase the concentration of the guest to such an extent as not to cause concentration quenching, and it is preferable that the concentration of the guest to the total amount of the p-type host and the n-type host be 1% to 9% by weight.

In this embodiment, the concept in which the guest in the p-type and n-type hosts is excited by the energy transfer from the exciplex of the p-type and n-type hosts not only enables confinement of the carriers and a reduction in the barrier to carrier injection into the light-emitting layer but also allows formation of an exciplex and the utilization of the energy transfer process from both of the singlet and triplet excited states of the exciplex, which leads to the formation of a highly efficient light-emitting element with a low drive voltage (i.e., power efficiency is significantly high).

### <Guest>

As the guest, a phosphorescent compound can be used; an organometallic complex is preferable, and in particular, an organometallic iridium complex is preferable. In consideration of energy transfer due to Förster mechanism, the molar absorption coefficient of the absorption band of the phosphorescent compound which is located on the longest wavelength side is preferably 2000 M⁻¹·cm⁻¹ or more, more preferably 5000 M⁻¹·cm⁻¹ or more.

Examples of compounds having such a high molar absorption coefficient are bis(3,5-dimethyl-2-phenylpyrazinato)(dipivaloylmethanato)iridium(III) (abbreviation: [Ir(mppr-Me)₂(dpm)]), (acetylacetonato)bis(4,6-diphenylpyrimidinato)iridium(III) (abbreviation: [Ir(dppm)₂(acac)]), and the like. In particular, when a material having a molar absorption coefficient of 5000 M⁻¹·cm⁻¹ or more, such as [Ir(dppm)₂(acac)], is used, a light-emitting element that can achieve an external quantum efficiency of about 30% can be obtained.

Other examples of phosphorescent compounds which can be used as the guest will be given. For example, examples of phosphorescent compounds having an emission peak at 440 nm to 520 nm include the following: organometallic iridium complexes having 4H-triazole skeletons, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃], and tris[4-(3-biphenyl)-5-isopropyl-3-phenyl-4H-1,2,4-triazolato]iridium(III) (abbreviation: [Ir(iPrptz-3b)₃]); organometallic iridium complexes having 1H-triazole skeletons, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptz1-Me)₃]); organometallic iridium complexes having imidazole skeletons, such as fac-tris[1-(2,6-diisopropylphenyl)-2-phenyl-1H-imidazole]iridium(III) (abbreviation: [Ir(iPrpmi)₃]) and tris[3-(2,6-dimethylphenyl)-7-methylimidazo[1,2-f]phenanthridinato]iridium(III) (abbreviation: [Ir(dmpimpt-Me)₃]); and organometallic iridium complexes in which a phenylpyridine derivative having an electron-withdrawing group is a ligand, such as bis[2-(4′,6′-difluorophenyl)pyridinato-N,C^{2′}]iridium(III)tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIracac). Among the above materials, the organometallic iridium complexes having 4H-triazole skeletons are particularly preferable because of their high reliability and high emission efficiency.

Examples of phosphorescent compounds having an emission peak at 520 nm to 600 nm include the following: organometallic iridium complexes having pyrimidine skeletons, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[4-(2-norbornyl)-6-phenylpyrimidinato]iridium(III) (endo- and exo-mixture) (abbreviation: [Ir(nbppm)₂(acac)]), and (acetylacetonato)bis[5-methyl-6-(2-methylphenyl)-4-phenylpyrimidinato]iridium(III) (abbreviation: [Ir(mpmppm)₂(acac)]); organometallic iridium complexes having pyrazine skeletons, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having pyridine skeletons, such as tris(2-phenylpyridinato-N,C^{2′})iridium(ITT) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), and bis(2-phenylquinolinato-N,C^{2′})iridium(III) acetylacetonate (abbreviation: [Ir(pq)₂(acac)]); and rare earth metal complexes such as tris(acetylacetonato)(monophenanthroline)terbium(III) (abbreviation: [Tb(acac)₃(Phen)]). Among the above materials, the organometallic iridium complexes having pyrimidine skeletons are particularly preferable because of their distinctively high reliability and emission efficiency.

Examples of the phosphorescent material having an emission peak at 600 nm to 700 nm include organometallic iridium complexes having pyrimidine skeletons, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and bis[4,6-di(naphthalen-1-yl)pyrimidinato] (dipivaloylmethanato)iridium(III) (abbreviation: [Ir(d1npm)₂(dpm)]); organometallic iridium complexes having pyrazine skeletons, such as (acetylacetonato)bis(2,3,5-triphenylpyrazinato)iridium(III) (abbreviation: [Ir(tppr)₂(acac)]), bis(2,3,5-triphenylpyrazinato) (dipivaloylmethanato)iridium(III) (abbreviation: [Ir(tppr)₂(dpm)]), and (acetylacetonato)bis[2,3-bis(4-fluorophenyl)quinoxalinato]iridium(III) (abbreviation: [Ir(Fdpq)₂(acac)]); organometallic iridium complexes having pyridine skeletons, such as tris(1-phenylisoquinolinato-N,C^{2′})iridium(III) (abbreviation: [Ir(piq)₃]) and bis(1-phenylisoquinolinato-N,C^{2′})iridium(III) acetylacetonate (abbreviation: [Ir(piq)₂(acac)]); a platinum complex such as 2,3,7,8,12,13,17,18-octaethyl-21H,23H-porphyrin platinum(II) (abbreviation: PtOEP); and rare earth metal complexes such as tris(1,3-diphenyl-1,3-propanedionato)(monophenanthroline)europium(III) (abbreviation: [Eu(DBM)₃(Phen)]) and tris[1-(2-thenyl)-3,3,3-trifluoroacetonato](monophenanthroline)europium(III) (abbreviation: [Eu(TTA)₃(Phen)]). Among the above materials, the organometallic iridium complexes having pyrimidine skeletons are particularly preferable because of their distinctively high reliability and emission efficiency. Further, the organometallic iridium complexes having pyrazine skeletons can provide red light emission with favorable chromaticity.

### <P-Type Host>

The p-type host is an organic compound with a hole-transport property. As such an organic compound, a π-electron rich heteroaromatic compound (e.g., a carbazole derivative or an indole derivative) or an aromatic amine compound can be preferably used. For example, the following can be given: 4-phenyl-4′-(9-phenyl-9H-carbazol-3-yl)triphenylamine (abbreviation: PCBA1BP), 4,4′-di(1-naphthyl)-4″-(9-phenyl-9H-carbazol-3-yl)triphenylamine (abbreviation: PCBNBB), 4,4′-bis[N-(1-naphthyl)-N-phenylamino]biphenyl (abbreviation: NPB or α-NPD), 3-[N-(1-naphthyl)-N-(9-phenylcarbazol-3-yl)amino]-9-phenylcarbazole (abbreviation: PCzPCN1), 4,4′,4″-tris[N-(1-naphthyl)-N-phenylamino]triphenylamine (abbreviation: 1′-TNATA), 2,7-bis[N-(4-diphenylaminophenyl)-N-phenylamino]-spiro-9,9′-bifluorene (abbreviation: DPA2SF), N,N′-bis(9-phenylcarbazol-3-yl)-N,N′-diphenylbenzene-1,3-diamine (abbreviation: PCA2B), N-(9,9-dimethyl-2-diphenylamino-9H-fluoren-7-yl)diphenylamine (abbreviation: DPNF), N,N′,N″-triphenyl-N,N′,N″-tris(9-phenylcarbazol-3-yl)benzene-1,3,5-triamine (abbreviation: PCA3B), 2-[N-(9-phenylcarbazol-3-yl)-N-phenylamino]spiro-9,9′-bifluorene (abbreviation: PCASF), 2-[N-(4-diphenylaminophenyl)-N-phenylamino]spiro-9,9′-bifluorene (abbreviation: DPASF), N,N′-bis[4-(carbazol-9-yl)phenyl]-N,N′-diphenyl-9,9-dimethylfluorene-2,7-diamine (abbreviation: YGA2F), N,N′-bis(3-methylphenyl)-N,N′-diphenyl-[1,1′-biphenyl]-4,4′-diamine (abbreviation: TPD), 4,4′-bis[N-(4-diphenylaminophenyl)-N-phenylamino]biphenyl (abbreviation: DPAB), N-(9,9-dimethyl-9H-fluoren-2-yl)-N-{9,9-dimethyl-2-[N′-phenyl-N′-(9,9-dimethyl-9H-fluoren-2-yl)amino]-9H-fluoren-7-yl}phenylamine (abbreviation: DFLADFL), 3-[N-(9-phenylcarbazol-3-yl)-N-phenylamino]-9-phenylcarbazole (abbreviation: PCzPCA1), 3-[N-(4-diphenylaminophenyl)-N-phenylamino]-9-phenylcarbazole (abbreviation: PCzDPA1), 3,6-bis[N-(4-diphenylaminophenyl)-N-phenylamino]-9-phenylcarbazole (abbreviation: PCzDPA2), 4,4′-bis(N-{4-[N′-(3-methylphenyl)-N-phenylamino]phenyl}-N-phenylamino)biphenyl (abbreviation: DNTPD), 3,6-bis[N-(4-diphenylaminophenyl)-N-(1-naphthyl)amino]-9-phenylcarbazole (abbreviation: PCzTPN2), 3,6-bis[N-(9-phenylcarbazol-3-yl)-N-phenylamino]-9-phenylcarbazole (abbreviation: PCzPCA2), and the like.

### <N-Type Host>

The n-type host is an organic compound with an electron-transport property. As such an organic compound, a π-electron deficient heteroaromatic compound such as a nitrogen-containing heteroaromatic compound, a metal complex having a quinoline skeleton or a benzoquinoline skeleton, a metal complex having an oxazole-based or thiazole-based ligand, or the like can be used.

Specific examples include the following: metal complexes such as bis(10-hydroxybenzo[h]quinolinato)berylium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: Zn(BOX)₂), and bis[2-(2-benzothiazolyl)phenolato]zinc(II) (abbreviation: Zn(BTZ)₂); heterocyclic compounds having polyazole skeletons, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), and 2-[3-(dibenzothiophen-4-yl)phenyl]-1-phenyl-1H-benzimidazole (abbreviation: mDBTBIm-II); heterocyclic compounds having quinoxaline skeletons or dibenzoquinoxaline skeletons, such as 2-[3-(dibenzothiophen-4-yl)phenyl]dibenzo[f,h]quinoxaline (abbreviation: 2mDBTPDBq-II), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBPDBq-II), 2-[3′-(dibenzothiophen-4-yl)biphenyl-3-yl]dibenzo[f,h]quinoxaline (abbreviation: 2mDBTBPDBq-II), 2-[4-(dibenzothiophen-4-yl)phenyl]dibenzo[f,h]quinoxaline (abbreviation: 2DBTPDBq-II), 2-[4-(3,6-diphenyl-9H-carbazol-9-yl)phenyl]dibenzo[f,h]quinoxaline (abbreviation: 2CzPDBq-III), and 2-[3′-(9H-carbazol-9-yl)biphenyl-3-yl]dibenzo[f,h]quinoxaline (abbreviation: 2mCzBPDBq); heterocyclic compounds having diazine skeletons (pyrimidine skeletons or pyrazine skeletons), such as 4,6-bis[3-(phenanthren-9-yl)phenyl]pyrimidine (abbreviation: 4,6mPnP2 Pm), 4,6-bis[3-(9H-carbazol-9-yl)phenyl]pyrimidine (abbreviation: 4,6mCzP2 Pm), and 4,6-bis[3-(4-dibenzothienyl)phenyl]pyrimidine (abbreviation: 4,6mDBTP2 Pm-II); and heterocyclic compounds having pyridine skeletons, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), and 3,3′,5,5′-tetra[(m-pyridyl)-phen-3-yl]biphenyl (abbreviation: BP4 mPy). Among the above materials, the heterocyclic compounds having quinoxaline skeletons or dibenzoquinoxaline skeletons, the heterocyclic compounds having diazine skeletons, and the heterocyclic compounds having pyridine skeletons are preferable because of their high reliability.

Note that in a light-emitting element of one embodiment of the present invention, a plurality of kinds of p-type hosts or a plurality of kinds of n-type hosts can be used.

As described above, one embodiment of the present invention not only enables confinement of carriers and a reduction in a barrier to carrier injection into the light-emitting layer but also allows formation of an exciplex and the utilization of the energy transfer process from both of the singlet and triplet excited states of the exciplex; thus, a light-emitting element with high emission efficiency can be obtained.

This embodiment can be combined with any other embodiment as appropriate.

### Embodiment 2

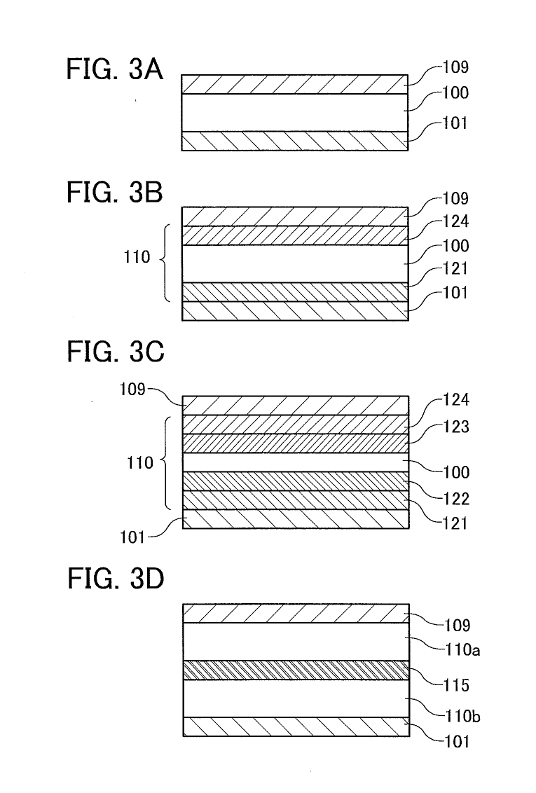

In this embodiment, a light-emitting element of one embodiment of the present invention will be described with reference to FIGS. 3A to 3D.

The light-emitting element of this embodiment includes an EL layer between a pair of electrodes (an anode and a cathode).

A light-emitting element illustrated in FIG. 3A includes only a stack 100 as an EL layer between an anode 101 and a cathode 109. Any of the stacks 100a to 100c described in Embodiment 1 may be applied to the stack 100 in this embodiment. Note that in each of the stacks, the layer 103 containing the p-type host is provided on the anode 101 side and the layer 104 containing the n-type host is provided on the cathode 109 side. At least one of the anode 101 and the cathode 109 has a property of transmitting visible light.

In the stack 100 of the light-emitting element illustrated in FIG. 3A, the layer 103 containing the p-type host functions as a hole-transport layer and blocks electrons. Further, the layer 104 containing the n-type host functions as an electron-transport layer and blocks holes. Accordingly, a hole-transport layer or an electron-transport layer does not need to be separately provided, which leads to simplification of a manufacturing process of the light-emitting element.

In a light-emitting element illustrated in FIG. 3B, an EL layer 110 includes, from the anode 101 side, a hole-injection layer 121, the stack 100, and an electron-injection layer 124.

The hole-injection layer 121 and the electron-injection layer 124 are preferably provided, in which case holes and electrons can be efficiently injected from the anode 101 and the cathode 109 to the EL layer 110 and energy efficiency can be thus improved.

In a light-emitting element illustrated in FIG. 3C, the EL layer 110 includes, from the anode 101 side, the hole-injection layer 121, a hole-transport layer 122, the stack 100, an electron-transport layer 123, and the electron-injection layer 124.

Although the layer containing the p-type host and the layer containing the n-type host in the stack 100 function as carrier-transport layers as described above, the hole-transport layer 122 and the electron-transport layer 123 are preferably provided in the EL layer 110, in which case electrons and holes can be injected more efficiently.

A light-emitting element illustrated in FIG. 3D includes a first EL layer 110a and a second EL layer 110b between the anode 101 and the cathode 109, and also includes a charge-generation region 115 between the first EL layer 110a and the second EL layer 110b.

Each of the EL layers contains at least an organic compound that is a light-emitting substance. In a light-emitting element of one embodiment of the present invention which includes a plurality of EL layers as in the light-emitting element illustrated in FIG. 3D, at least one of the EL layers includes the stack described in Embodiment 1. In FIG. 3D, at least one of the first EL layer 110a and the second EL layer 110b includes the stack 100 described in Embodiment 1.

The charge-generation region 115 has a function of injecting electrons into one of the EL layers and injecting holes into the other of the EL layers when a voltage is applied between the anode 101 and the cathode 109. In the case of this embodiment, when a voltage is applied such that the potential of the anode 101 is higher than that of the cathode 109, the charge-generation region 115 injects electrons into the first EL layer 110a and injects holes into the second EL layer 110b. Note that by formation of the charge-generation region 115, an increase in drive voltage in the case where the EL layers are stacked can be suppressed.

In view of light extraction efficiency, it is preferable that the charge-generation region 115 have a property of transmitting visible light. The charge-generation region 115 functions even when it has lower conductivity than the anode 101 or the cathode 109.

### <Anode>

The anode 101 can be formed using one or more kinds of conductive metals and alloys, conductive compounds, and the like. In particular, it is preferable to use a material with a high work function (4.0 eV or more). Examples include indium tin oxide (ITO), indium tin oxide containing silicon or silicon oxide (ITSO), indium zinc oxide, indium oxide containing tungsten oxide and zinc oxide, graphene, gold, platinum, nickel, tungsten, chromium, molybdenum, iron, cobalt, copper, palladium, and a nitride of a metal material (e.g., titanium nitride).

When the anode is in contact with the charge-generation region, any of a variety of conductive materials can be used regardless of their work functions; for example, aluminum, silver, an alloy containing aluminum, or the like can be used.

### <Cathode>

The cathode 109 can be formed using one or more kinds of conductive metals and alloys, conductive compounds, and the like. In particular, it is preferable to use a material with a low work function (3.8 eV or less). Examples include aluminum, silver, an element belonging to Group 1 or 2 of the periodic table (e.g., an alkali metal such as lithium or cesium, an alkaline earth metal such as calcium or strontium, or magnesium), an alloy containing any of these elements (e.g., Mg—Ag or Al—Li), a rare earth metal such as europium or ytterbium, and an alloy containing any of these rare earth metals.

Note that in the case where the cathode is in contact with the charge-generation region, any of a variety of conductive materials can be used regardless of their work functions. For example, ITO, ITSO, or the like can be used.

The electrodes may each be formed by a vacuum evaporation method or a sputtering method. Alternatively, when a silver paste or the like is used, a coating method or an inkjet method may be used.

### <Hole-Injection Layer>

The hole-injection layer 121 contains a substance having a high hole-injection property.

Examples of the substance having a high hole-injection property include metal oxides such as molybdenum oxide, titanium oxide, vanadium oxide, rhenium oxide, ruthenium oxide, chromium oxide, zirconium oxide, hafnium oxide, tantalum oxide, silver oxide, tungsten oxide, and manganese oxide.

Alternatively, it is possible to use a phthalocyanine-based compound such as phthalocyanine (abbreviation: H₂Pc) or copper(II) phthalocyanine (abbreviation: CuPc).

Further alternatively, it is possible to use an aromatic amine compound which is a low molecular organic compound, such as 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), DPAB, DNTPD, 1,3,5-tris[N-(4-diphenylaminophenyl)-N-phenylamino]benzene (abbreviation: DPA3B), PCzPCA1, PCzPCA2, or PCzPCN1.

Further alternatively, it is possible to use a high molecular compound such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), or poly[N,N′-bis(4-butylphenyl)-N,N′-bis(phenyl)benzidine] (abbreviation: Poly-TPD), or a high molecular compound to which acid is added, such as poly(3,4-ethylenedioxythiophene)/poly(styrenesulfonic acid) (abbreviation: PEDOT/PSS) or polyaniline/poly(styrenesulfonic acid) (abbreviation: PAni/PSS).

The hole-injection layer 121 may serve as the charge-generation region. When the hole-injection layer 121 in contact with the anode serves as the charge-generation region, any of a variety of conductive materials can be used for the anode regardless of their work functions. Materials contained in the charge-generation region will be described below.

### <Hole-Transport Layer>

The hole-transport layer 122 contains an organic compound with a hole-transport property. The hole-transport layer can be formed using the above-mentioned p-type host, for example.

Other examples of the organic compound with a hole-transport property are aromatic amine compounds such as 4-phenyl-4′-(9-phenylfluoren-9-yl)triphenylamine (abbreviation: BPAFLP), 4,4′-bis[N-(9,9-dimethylfluoren-2-yl)-N-phenylamino]biphenyl (abbreviation: DFLDPBi), and 4,4′-bis[N-(spiro-9,9′-bifluoren-2-yl)-N-phenylamino]biphenyl (abbreviation: BSPB).

Alternatively, it is possible to use a carbazole derivative such as 4,4′-di(N-carbazolyl)biphenyl (abbreviation: CBP), 9-[4-(10-phenyl-9-anthracenyl)phenyl]-9H-carbazole (abbreviation: CzPA), or 9-phenyl-3-[4-(10-phenyl-9-anthryl)phenyl]-9H-carbazole (abbreviation: PCzPA).

Further alternatively, it is possible to use an aromatic hydrocarbon compound such as 2-tert-butyl-9,10-di(2-naphthyl)anthracene (abbreviation: t-BuDNA), 9,10-di(2-naphthyl)anthracene (abbreviation: DNA), or 9,10-diphenylanthracene (abbreviation: DPAnth).

A high molecular compound such as PVK, PVTPA, PTPDMA, or Poly-TPD can also be used.

### <Electron-Transport Layer>

The electron-transport layer 123 contains an organic compound with an electron-transport property. The electron-transport layer can be formed using the above-mentioned n-type host, for example.

A metal complex such as tris(8-quinolinolato)aluminum(III) (abbreviation: Alq) or tris(4-methyl-8-quinolinolato)aluminum(III) (abbreviation: Almq₃) can be used for the electron-transport layer 123.

Further, a heteroaromatic compound such as bathophenanthroline (abbreviation: BPhen), bathocuproine (abbreviation: BCP), 3-(4-tert-butylphenyl)-4-(4-ethylphenyl)-5-(4-biphenylyl)-1,2,4-triazole (abbreviation: p-EtTAZ), or 4,4′-bis(5-methylbenzoxazol-2-yl)stilbene (abbreviation: BzOs) can be used.

Further, a high molecular compound such as poly(2,5-pyridinediyl) (abbreviation: PPy), poly[(9,9-dihexylfluorene-2,7-diyl)-co-(pyridine-3,5-diyl)] (abbreviation: PF-Py), or poly[(9,9-dioctylfluorene-2,7-diyl)-co-(2,2′-bipyridine-6,6′-diyl)] (abbreviation: PF-BPy) can be used.

<Electron-Injection Layer>

The electron-injection layer 124 contains a substance having a high electron-injection property.

Examples of the substance having a high electron-injection property include an alkali metal, an alkaline earth metal, a rare earth metal, and a compound thereof (e.g., an oxide thereof, a carbonate thereof, and a halide thereof), such as lithium, cesium, calcium, lithium oxide, lithium carbonate, cesium carbonate, lithium fluoride, cesium fluoride, calcium fluoride, and erbium fluoride.

The electron-injection layer 124 may serve as the charge-generation region. When the electron-injection layer 124 in contact with the cathode serves as the charge-generation region, any of a variety of conductive materials can be used for the cathode regardless of their work functions. Materials contained in the charge-generation region will be described below.

### <Charge-Generation Region>

The charge-generation region may have either a structure in which an electron acceptor (acceptor) is added to an organic compound with a hole-transport property or a structure in which an electron donor (donor) is added to an organic compound with an electron-transport property. Alternatively, both of these structures may be stacked.

As examples of an organic compound with a hole-transport property, the above p-type host and the above materials which can be used for the hole-transport layer can be given, and as examples of an organic compound with an electron-transport property, the above n-type host and the above materials which can be used for the electron-transport layer can be given.

Further, as the electron acceptor, 7,7,8,8-tetracyano-2,3,5,6-tetrafluoroquinodimethane (abbreviation: F₄-TCNQ), chloranil, and the like can be given. In addition, transition metal oxides can be given. Oxides of the metals that belong to Groups 4 to 8 of the periodic table can be given. Specifically, vanadium oxide, niobium oxide, tantalum oxide, chromium oxide, molybdenum oxide, tungsten oxide, manganese oxide, and rhenium oxide are preferable in that their electron-accepting properties are high. Among these oxides, molybdenum oxide is particularly preferable in that it is stable in the air, has a low hygroscopic property, and is easy to handle.

Further, as the electron donor, it is possible to use an alkali metal, an alkaline earth metal, a rare earth metal, a metal belonging to Group 2 or Group 13 of the periodic table, or an oxide or a carbonate thereof. Specifically, lithium, cesium, magnesium, calcium, ytterbium, indium, lithium oxide, cesium carbonate, or the like is preferably used. Alternatively, an organic compound such as tetrathianaphthacene may be used as the electron donor.

The above-described layers included in the EL layer and the charge-generation region can each be formed by any of the following methods: an evaporation method (including a vacuum evaporation method), an inkjet method, a coating method, and the like.

This embodiment can be combined with any other embodiment as appropriate.

### Embodiment 3

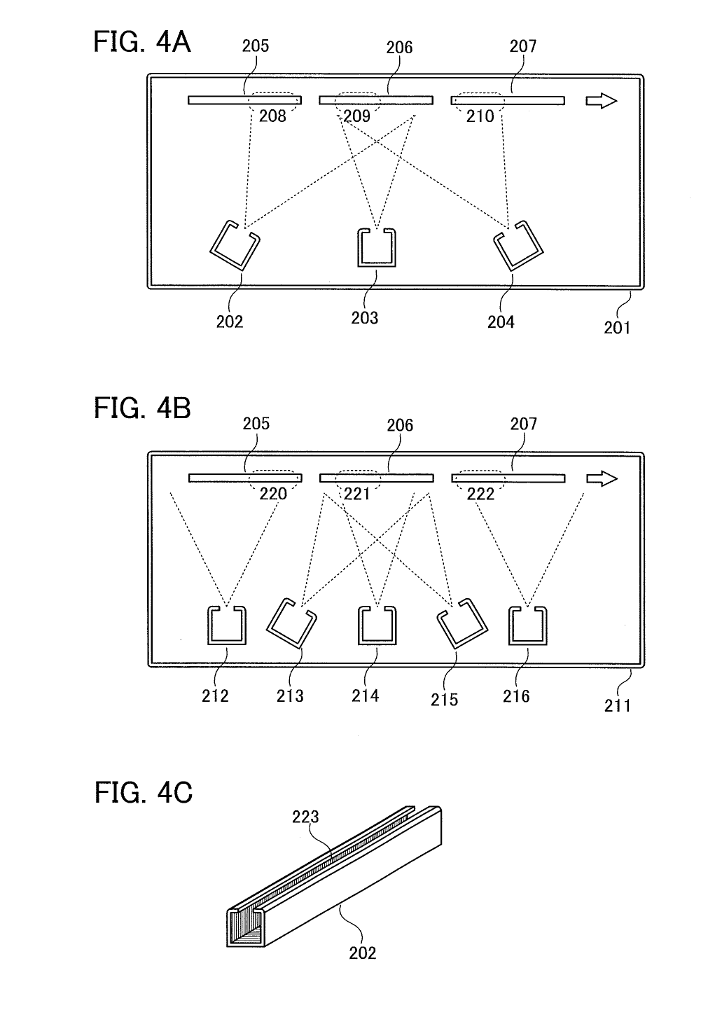

In this embodiment, apparatuses for manufacturing a light-emitting element of one embodiment of the present invention will be described with reference to FIGS. 4A to 4C.

A manufacturing apparatus illustrated in FIG. 4A includes a first deposition material holding portion 202, a second deposition material holding portion 203, and a third deposition material holding portion 204 in a vacuum chamber 201. The deposition material holding portions described in this embodiment each have a linear opening portion (see a linear opening portion 223 of the first deposition material holding portion 202 which is illustrated in FIG. 4C) and can be used to evaporate a deposition material therein by a resistance heating method.

In this embodiment, the first deposition material holding portion 202, the second deposition material holding portion 203, and the third deposition material holding portion 204 cause the p-type host, the guest, and the n-type host to evaporate, respectively. The deposition material holding portions may each be provided with a shutter. Furthermore, it is preferable that the temperatures of the deposition material holding portions can be controlled independently.

Furthermore, the opening portions of the deposition material holding portions may have different shapes, sizes, or the like so that, for example, organic compounds are scattered from the first deposition material holding portion 202 and the third deposition material holding portion 204 to a wide area, whereas an organic compound is scattered from the second deposition material holding portion 203 to a narrower area. Further, the opening portions of the deposition material holding portions may be oriented in different directions as illustrated in FIG. 4A.

Inside the vacuum chamber 201, one or more substrates, preferably two or more substrates (in FIG. 4A, substrates 205, 206, and 207), may be placed and moved at an appropriate speed from left to right as illustrated (i.e., in a direction substantially perpendicular to the orientations of the opening portions of the deposition material holding portions). Note that the deposition material holding portions may be at different distances from the substrates.

In the manufacturing apparatus illustrated in FIG. 4A, in a region 208, the p-type host scattered from the first deposition material holding portion 202 is mainly deposited. In a region 209, the p-type host scattered from the first deposition material holding portion 202, the guest scattered from the second deposition material holding portion 203, and the n-type host scattered from the third deposition material holding portion 204 are deposited at a certain ratio. Furthermore, in a region 210, the n-type host scattered from the third deposition material holding portion 204 is mainly deposited.

Accordingly, while the substrates 205 to 207 are moved from left to right, the layer 103 containing the p-type host is formed first, the light-emitting layer 102 is formed next, and the layer 104 containing the n-type host is then formed. In some cases, the p-type transition region 113 is formed between the layer 103 containing the p-type host and the light-emitting layer 102, and the n-type transition region 114 is formed between the layer 104 containing the n-type host and the light-emitting layer 102, as in the stack 100b described in Embodiment 1. In other cases, as in the stack 100c described in Embodiment 1, a distinct boundary between the light-emitting layer and the layer 103 containing the p-type host or the layer 104 containing the n-type host is not formed.

A manufacturing apparatus illustrated in FIG. 4B includes a first deposition material holding portion 212, a second deposition material holding portion 213, a third deposition material holding portion 214, a fourth deposition material holding portion 215, and a fifth deposition material holding portion 216 in a vacuum chamber 211. In this embodiment, the first deposition material holding portion 212 and the second deposition material holding portion 213 cause the p-type host to evaporate; the third deposition material holding portion 214 causes the guest to evaporate; and the fourth deposition material holding portion 215 and the fifth deposition material holding portion 216 cause the n-type host to evaporate.

In the manufacturing apparatus illustrated in FIG. 4B, in a region 220, the p-type host scattered from the first deposition material holding portion 212 is mainly deposited. In a region 221, the p-type host scattered from the second deposition material holding portion 213, the guest scattered from the third deposition material holding portion 214, and the n-type host scattered from the fourth deposition material holding portion 215 are deposited at a certain ratio. Furthermore, in a region 222, the n-type host scattered from the fifth deposition material holding portion 216 is mainly deposited.

The manufacturing apparatus illustrated in FIG. 4B can provide drastic changes in the concentrations of the p-type host and the n-type host at the interface between the light-emitting layer 102 and the layer 103 containing the p-type host and at the interface between the light-emitting layer 102 and the layer 104 containing the n-type host as in the stack 100a described in Embodiment 1.

This embodiment can be combined with any other embodiment as appropriate.

### Embodiment 4

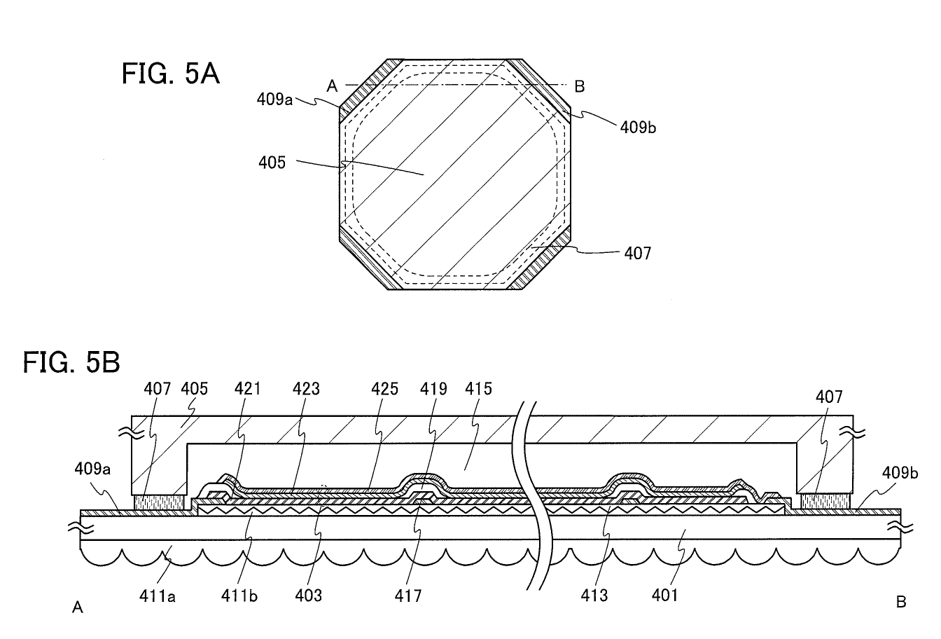

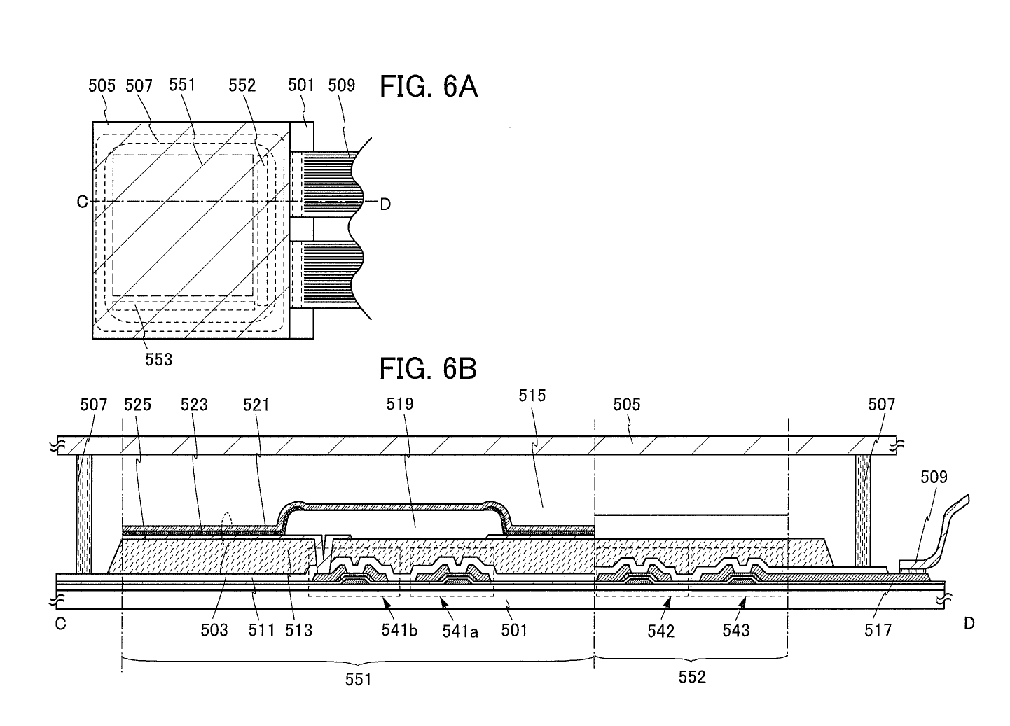

In this embodiment, a light-emitting device of one embodiment of the present invention will be described with reference to FIGS. 5A and 5B and FIGS. 6A and 6B. The light-emitting device of this embodiment includes a light-emitting element of one embodiment of the present invention. The light-emitting element has high emission efficiency and thus a light-emitting device with low power consumption can be obtained.

FIG. 5A is a plan view of a light-emitting device of one embodiment of the present invention, and FIG. 5B is a cross-sectional view taken along a dashed-dotted line A-B in FIG. 5A.

In the light-emitting device of this embodiment, a light-emitting element 403 is provided in a space 415 surrounded by a support substrate 401, a sealing substrate 405, and a sealing material 407. The light-emitting element 403 is an organic EL element having a bottom-emission structure; specifically, the first electrode 421 which transmits visible light is provided over the support substrate 401, the EL layer 423 is provided over the first electrode 421, and the second electrode 425 which reflects visible light is provided over the EL layer 423. The EL layer 423 includes any one of the stacks described in Embodiment 1.

A first terminal 409a is electrically connected to an auxiliary wiring 417 and the first electrode 421. An insulating layer 419 is provided over the first electrode 421 in a region which overlaps with the auxiliary wiring 417. The first terminal 409a is electrically insulated from the second electrode 425 by the insulating layer 419. A second terminal 409b is electrically connected to the second electrode 425. Note that although the first electrode 421 is formed over the auxiliary wiring 417 in this embodiment, the auxiliary wiring 417 may be formed over the first electrode 421.

A light extraction structure 411a is preferably provided at the interface between the support substrate 401 and the atmosphere. When provided at the interface between the support substrate 401 and the atmosphere, the light extraction structure 411a can reduce light which cannot be extracted to the atmosphere due to total reflection, resulting in an increase in the light extraction efficiency of the light-emitting device.

In addition, a light extraction structure 411b is preferably provided at the interface between the light-emitting element 403 and the support substrate 401. In the case where the light extraction structure 411b has unevenness, a planarization layer 413 is preferably provided between the light extraction structure 411b and the first electrode 421. Accordingly, the first electrode 421 can be a flat film, and generation of leakage current in the EL layer 423 due to the unevenness of the first electrode 421 can be prevented. Further, because of the light extraction structure 411b at the interface between the planarization layer 413 and the support substrate 401, light which cannot be extracted to the atmosphere due to total reflection can be reduced, so that the light extraction efficiency of the light-emitting device can be increased.

As a material of the light extraction structure 411a and the light extraction structure 411b, a resin can be used, for example. Alternatively, for the light extraction structure 411a and the light extraction structure 411b, a hemispherical lens, a micro lens array, a film provided with an uneven surface structure, a light diffusing film, or the like can be used. For example, the light extraction structure 411a and the light extraction structure 411b can be formed by attaching the lens or film to the support substrate 401 with an adhesive or the like which has substantially the same refractive index as the support substrate 401 or the lens or film.

The surface of the planarization layer 413 which is in contact with the first electrode 421 is flatter than the surface of the planarization layer 413 which is in contact with the light extraction structure 411b. As a material of the planarization layer 413, glass, liquid, a resin, or the like having a light-transmitting property and a high refractive index can be used.

FIG. 6A is a plan view of a light-emitting device of one embodiment of the present invention, and FIG. 6B is a cross-sectional view taken along a dashed-dotted line C-D in FIG. 6A.

An active matrix light-emitting device in this embodiment includes, over a support substrate 501, a light-emitting portion 551, a driver circuit portion 552 (gate side driver circuit portion), a driver circuit portion 553 (source side driver circuit portion), and a sealing material 507. The light-emitting portion 551 and the driver circuit portions 552 and 553 are sealed in a space 515 surrounded by the support substrate 501, the sealing substrate 505, and the sealing material 507.

The light-emitting portion 551 illustrated in FIG. 6B includes a plurality of light-emitting units each including a switching transistor 541a, a current control transistor 541b, and a second electrode 525 electrically connected to a wiring (a source electrode or a drain electrode) of the transistor 541b.

A light-emitting element 503 has a bottom-emission structure and includes a first electrode 521, an EL layer 523, and the second electrode 525 which transmits visible light. Further, a partition 519 is formed so as to cover an end portion of the second electrode 525.

Over the support substrate 501, a lead wiring 517 for connecting an external input terminal through which a signal (e.g., a video signal, a clock signal, a start signal, or a reset signal) or a potential from the outside is transmitted to the driver circuit portion 552 or 553 is provided. Here, an example is described in which a flexible printed circuit (FPC) 509 is provided as the external input terminal. Note that a printed wiring board (PWB) may be attached to the FPC 509. In this specification, the light-emitting device includes in its category the light-emitting device itself and the light-emitting device provided with the FPC or the PWB.

The driver circuit portions 552 and 553 include a plurality of transistors. FIG. 6B illustrates an example in which the driver circuit portion 552 has a CMOS circuit which is a combination of an n-channel transistor 542 and a p-channel transistor 543. A circuit included in the driver circuit portion can be formed with various types of circuits such as a CMOS circuit, a PMOS circuit, or an NMOS circuit. The present invention is not limited to a driver-integrated type described in this embodiment in which the driver circuit is formed over the substrate over which the light-emitting portion is formed. The driver circuit can be formed over a substrate that is different from the substrate over which the light-emitting portion is formed.

To prevent an increase in the number of manufacturing steps, the lead wiring 517 is preferably formed using the same material and the same step(s) as those of the electrode or the wiring in the light-emitting portion or the driver circuit portion. Described in this embodiment is an example in which the lead wiring 517 is formed using the same material and the same step(s) as those of the source electrodes and the drain electrodes of the transistors included in the light-emitting portion 551 and the driver circuit portion 552.

In FIG. 6B, the sealing material 507 is in contact with a first insulating layer 511 over the lead wiring 517. The adhesion of the sealing material 507 to metal is low in some cases. Therefore, the sealing material 507 is preferably in contact with an inorganic insulating film over the lead wiring 517. Such a structure enables a light-emitting device to have high sealing capability, high adhesion, and high reliability. Examples of the inorganic insulating film include oxide films of metals and semiconductors, nitride films of metals and semiconductors, and oxynitride films of metals and semiconductors, and specifically, a silicon oxide film, a silicon nitride film, a silicon oxynitride film, a silicon nitride oxide film, an aluminum oxide film, a titanium oxide film, and the like.

The first insulating layer 511 has an effect of preventing diffusion of impurities into a semiconductor included in the transistor. As the second insulating layer 513, an insulating film having a planarization function is preferably selected in order to reduce surface unevenness due to the transistor.

There is no particular limitation on the structure and materials of the transistor used in the light-emitting device of one embodiment of the present invention. A top-gate transistor may be used, or a bottom-gate transistor such as an inverted staggered transistor may be used. The transistor may be a channel-etched transistor or a channel-protective transistor.

A semiconductor layer can be formed using silicon or an oxide semiconductor such as an In—Ga—Zn-based metal oxide.

A structure of the present invention is not limited to the light-emitting device using a separate coloring method, which is described as an example in this embodiment. For example, a color filter method or a color conversion method may be used. Further, a light-emitting device of one embodiment of the present invention may be provided with a color filter, a black matrix, a desiccant, or the like.

This embodiment can be combined with any other embodiment as appropriate.

### Embodiment 5

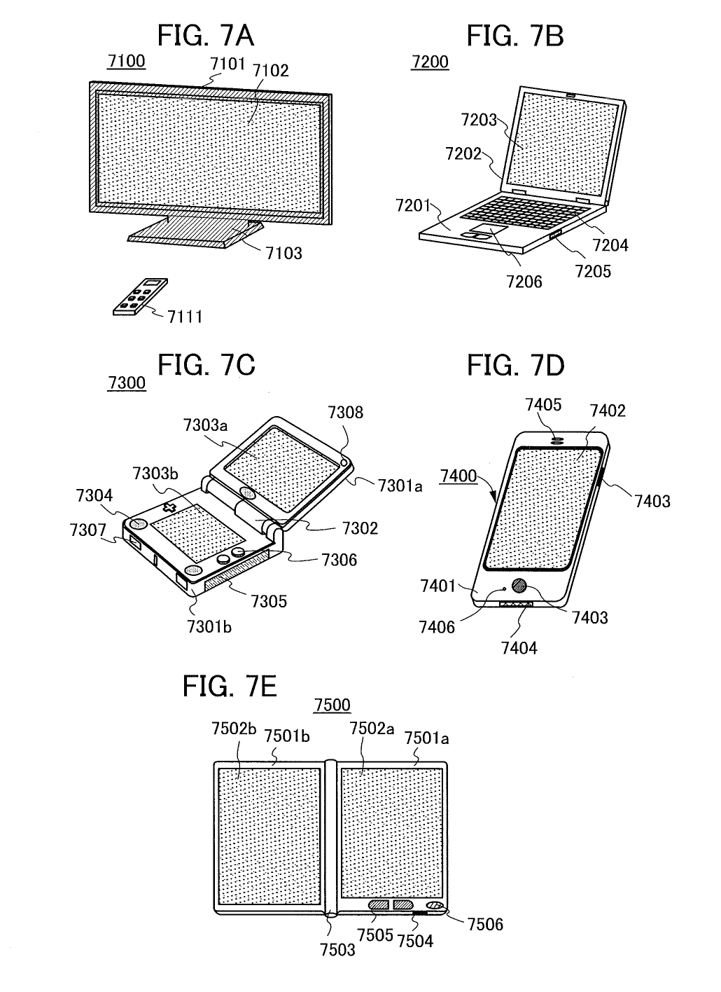

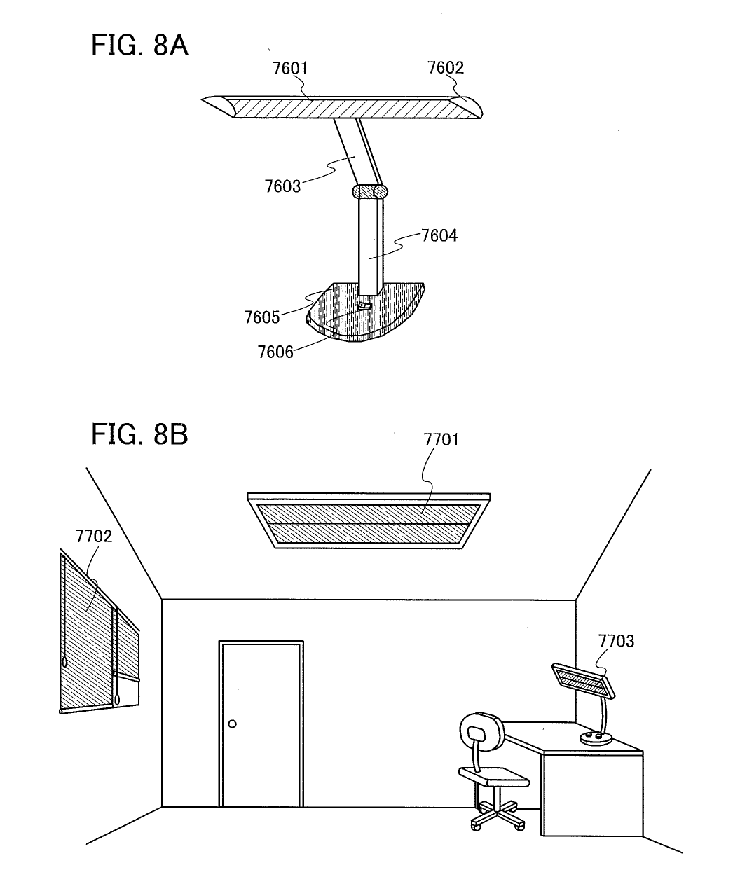

In this embodiment, examples of electronic devices and lighting devices to which the light-emitting device of one embodiment of the present invention is applied will be described with reference to FIGS. 7A to 7E and FIGS. 8A and 8B.

Electronic devices of this embodiment each include the light-emitting device of one embodiment of the present invention in a display portion. Lighting devices of this embodiment each include the light-emitting device of one embodiment of the present invention in a light-emitting portion (lighting portion). An electronic device and a lighting device with low power consumption can be provided by adopting the light-emitting device of one embodiment of the present invention.

Examples of electronic devices to which the light-emitting device is applied are television devices (also referred to as TV or television receivers), monitors for computers and the like, cameras such as digital cameras and digital video cameras, digital photo frames, cellular phones (also referred to as portable telephone devices), portable game machines, portable information terminals, audio playback devices, large game machines such as pin-ball machines, and the like. Specific examples of these electronic devices and lighting devices are illustrated in FIGS. 7A to 7E and FIGS. 8A and 8B.

FIG. 7A illustrates an example of a television device. In a television device 7100, a display portion 7102 is incorporated in a housing 7101. The display portion 7102 is capable of displaying images. The light-emitting device of one embodiment of the present invention can be used for the display portion 7102. In addition, here, the housing 7101 is supported by a stand 7103.

The television device 7100 can be operated with an operation switch provided in the housing 7101 or a separate remote controller 7111. With operation keys of the remote controller 7111, channels and volume can be controlled and images displayed on the display portion 7102 can be controlled. The remote controller 7111 may be provided with a display portion for displaying data output from the remote controller 7111.

Note that the television device 7100 is provided with a receiver, a modem, and the like. With the use of the receiver, general television broadcasting can be received. Moreover, when the television device is connected to a communication network with or without wires via the modem, one-way (from a sender to a receiver) or two-way (between a sender and a receiver or between receivers) information communication can be performed.

FIG. 7B illustrates an example of a computer. A computer 7200 includes a main body 7201, a housing 7202, a display portion 7203, a keyboard 7204, an external connection port 7205, a pointing device 7206, and the like. Note that this computer is manufactured by using the light-emitting device of one embodiment of the present invention for the display portion 7203.

FIG. 7C illustrates an example of a portable game machine. A portable game machine 7300 has two housings, a housing 7301a and a housing 7301b, which are connected with a joint portion 7302 so that the portable game machine can be opened and closed. The housing 7301a incorporates a display portion 7303a, and the housing 7301b incorporates a display portion 7303b. In addition, the portable game machine illustrated in FIG. 7C includes a speaker portion 7304, a recording medium insertion portion 7305, an operation key 7306, a connection terminal 7307, a sensor 7308 (a sensor having a function of measuring or sensing force, displacement, position, speed, acceleration, angular velocity, rotational frequency, distance, light, liquid, magnetism, temperature, chemical substance, sound, time, hardness, electric field, electric current, voltage, electric power, radiation, flow rate, humidity, gradient, oscillation, odor, or infrared rays), an LED lamp, a microphone, and the like. It is needless to say that the structure of the portable game machine is not limited to the above structure as long as the light-emitting device of one embodiment of the present invention is used for at least either the display portion 7303a or the display portion 7303b, or both, and may include other accessories as appropriate. The portable game machine illustrated in FIG. 7C has a function of reading out a program or data stored in a recoding medium to display it on the display portion, and a function of sharing information with another portable game machine by wireless communication. Note that functions of the portable game machine illustrated in FIG. 7C are not limited to them, and the portable game machine can have various functions.

FIG. 7D illustrates an example of a cellular phone. A cellular phone 7400 is provided with a display portion 7402 incorporated in a housing 7401, an operation button 7403, an external connection port 7404, a speaker 7405, a microphone 7406, and the like. Note that the cellular phone 7400 is manufactured by using the light-emitting device of one embodiment of the present invention for the display portion 7402.

When the display portion 7402 of the cellular phone 7400 illustrated in FIG. 7D is touched with a finger or the like, data can be input into the cellular phone. Further, operations such as making a call and creating an e-mail can be performed by touching the display portion 7402 with a finger or the like.

There are mainly three screen modes of the display portion 7402. The first mode is a display mode mainly for displaying an image. The second mode is an input mode mainly for inputting data such as characters. The third mode is a display-and-input mode in which two modes of the display mode and the input mode are combined.

For example, in the case of making a call or creating e-mail, a character input mode mainly for inputting characters is selected for the display portion 7402 so that characters displayed on the screen can be input.

When a sensing device including a sensor such as a gyroscope sensor or an acceleration sensor for detecting inclination is provided inside the cellular phone 7400, display on the screen of the display portion 7402 can be automatically changed in direction by determining the orientation of the cellular phone 7400 (whether the cellular phone 7400 is placed horizontally or vertically for a landscape mode or a portrait mode).

The screen modes are changed by touch on the display portion 7402 or operation with the operation button 7403 of the housing 7401. The screen modes can be switched depending on the kind of images displayed on the display portion 7402. For example, when a signal of an image displayed on the display portion is a signal of moving image data, the screen mode is switched to the display mode. When the signal is a signal of text data, the screen mode is switched to the input mode.

Moreover, in the input mode, if a signal detected by an optical sensor in the display portion 7402 is detected and the input by touch on the display portion 7402 is not performed for a certain period, the screen mode may be controlled so as to be changed from the input mode to the display mode.

The display portion 7402 may function as an image sensor. For example, an image of a palm print, a fingerprint, or the like is taken by touch on the display portion 7402 with the palm or the finger, whereby personal authentication can be performed. Further, when a backlight or a sensing light source which emits near-infrared light is provided in the display portion, an image of a finger vein, a palm vein, or the like can be taken.

FIG. 7E illustrates an example of a fordable tablet terminal (in an open state). A tablet terminal 7500 includes a housing 7501a, a housing 7501b, a display portion 7502a, and a display portion 7502b. The housing 7501a and the housing 7501b are connected by a hinge 7503 and can be opened and closed using the hinge 7503 as an axis. The housing 7501a includes a power switch 7504, operation keys 7505, a speaker 7506, and the like. Note that the tablet terminal 7500 is manufactured by using the light-emitting device of one embodiment of the present invention for either the display portion 7502a or the display portion 7502b, or both.

Part of the display portion 7502a or the display portion 7502b can be used as a touch panel region, where data can be input by touching displayed operation keys. For example, a keyboard can be displayed on the entire region of the display portion 7502a so that the display portion 7502a is used as a touch screen, and the display portion 7502b can be used as a display screen.

FIG. 8A illustrates a desk lamp, which includes a lighting portion 7601, a shade 7602, an adjustable arm 7603, a support 7604, a base 7605, and a power switch 7606. The desk lamp is manufactured by using the light-emitting device of one embodiment of the present invention for the lighting portion 7601. Note that the lamp also includes ceiling lights, wall lights, and the like in its category.

FIG. 8B illustrates an example in which the light-emitting device of one embodiment of the present invention is used for an indoor lamp 7701. Since the light-emitting device of one embodiment of the present invention can have a larger area, it can be used as a large-area lighting device. In addition, the light-emitting device can be used as a roll-type lamp 7702. As illustrated in FIG. 8B, a desk lamp 7703 described with reference to FIG. 8A may be used in a room provided with the indoor lamp 7701.

This embodiment can be combined with any other embodiment as appropriate.

### Example 1

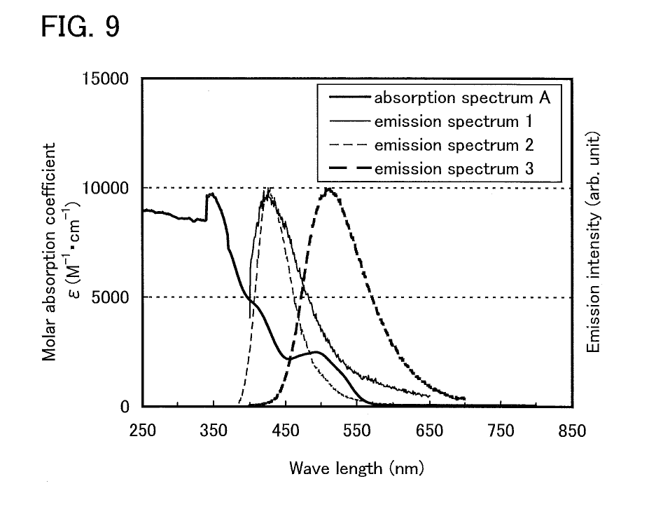

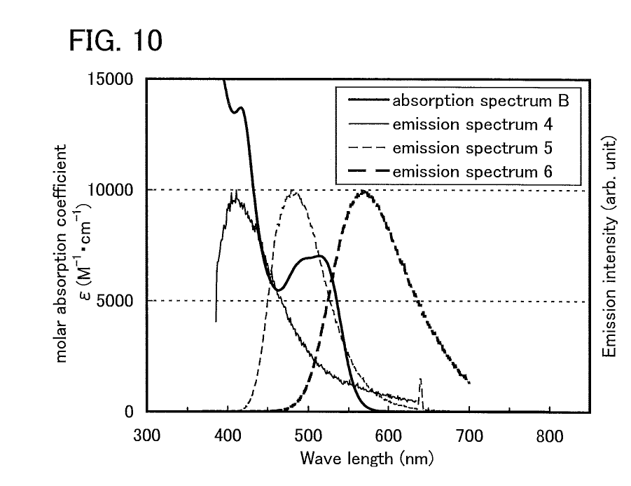

In this example, examples of a combination of an n-type host, a p-type host, and a guest which is applicable to a light-emitting element of one embodiment of the present invention will be described with reference to FIG. 9 and FIG. 10.

An n-type host used in this example is 2-[3-(dibenzothiophen-4-yl)phenyl]dibenzo[f,h]quinoxaline (abbreviation: 2mDBTPDBq-II). P-type hosts used in this example are 4,4′-di(1-naphthyl)-4″-(9-phenyl-9H-carbazol-3-yl)triphenylamine (abbreviation: PCBNBB) and 3-[N-(1-naphthyl)-N-(9-phenylcarbazol-3-yl)amino]-9-phenylcarbazole (abbreviation: PCzPCN1). Guests used in this example are bis(3,5-dimethyl-2-phenylpyrazinato)(dipivaloylmethanato)iridium(III) (abbreviation: [Ir(mppr-Me)₂(dpm)]) and (acetylacetonato)bis(4,6-diphenylpyrimidinato)iridium(III) (abbreviation: [Ir(dppm)₂(acac)]).

Structural formulae of the materials used in this example and their physical properties are shown below. Note that T₁ levels of the materials were evaluated using peak values of phosphorescence spectra at 10 K.

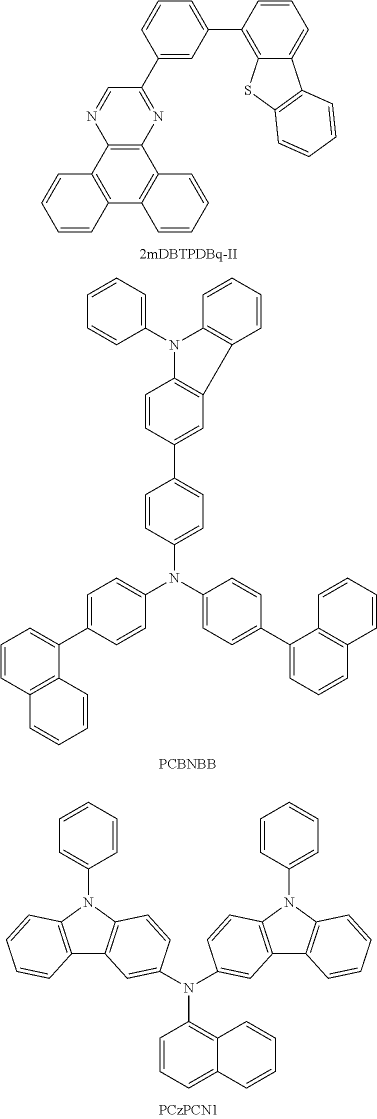

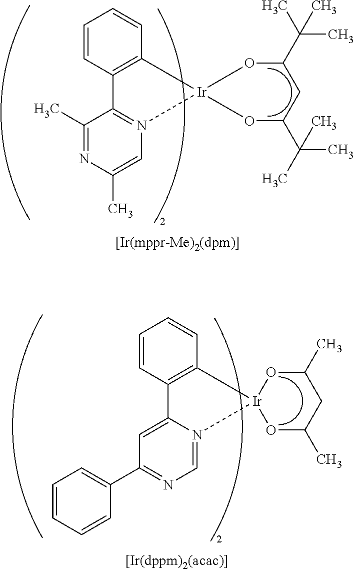

TABLE 1

| | | LUMO | HOMO | T₁ |
|---|---|---|---|---|
| | | Level | Level | Level |
| N-type Host | 2mDBTPDBq-II | −2.78 eV | −5.88 eV | 2.54 eV |
| P-type Host | PCBNBB | −2.31 eV | −5.46 eV | 2.40 eV |
| | PCzPCN1 | −2.31 eV | −5.15 eV | 2.21 eV |
| Guest | [Ir(mppr-Me)₂(dpm)] | −2.77 eV | −5.50 eV | 2.10 eV |
| | [Ir(dppm)₂(acac)] | −2.98 eV | −5.56 eV | 2.09 eV |

In a region where 2mDBTPDBq-II and PCBNBB are mixed, the LUMO level and the HOMO level are −2.78 eV and −5.46 eV, respectively, which are substantially equal to the LUMO level and the HOMO level of [Ir(mppr-Me)₂(dpm)], respectively. On the other hand, both the LUMO level and the HOMO level of [Ir(dppm)₂(acac)] are lower than those above; thus, it is found that [Ir(dppm)₂(acac)] is likely to trap electrons. This indicates that the probability of the direct recombination process is higher in the case of using [Ir(dppm)₂(acac)] as the guest than in the case of using [Ir(mppr-Me)₂(dpm)].

In a region where 2mDBTPDBq-II and PCzPCN1 are mixed, the LUMO level is −2.78 eV and the HOMO level is −5.15 eV. That is, the HOMO level of [Ir(mppr-Me)₂(dpm)] is lower than that of the region but the LUMO level of [Ir(mppr-Me)₂(dpm)] is substantially equal to that of the region. On the other hand, the LUMO level and the HOMO level of [Ir(dppm)₂(acac)] are lower than those of the region; thus, it is suggested that [Ir(dppm)₂(acac)] is likely to trap electrons and the probability of the direct recombination process is high.

In addition, the T₁ level of each of [Ir(mppr-Me)₂(dpm)] and [Ir(dppm)₂(acac)] is lower than the T₁ level of each of 2mDBTPDBq-II, PCBNBB, and PCzPCN1 by 0.1 eV or more. Thus, there is a low probability that triplet excitation energy of [Ir(mppr-Me)₂(dpm)] or [Ir(dppm)₂(acac)] in a triplet excited state is transferred so that 2mDBTPDBq-II, PCBNBB, or PCzPCN1 is brought into a triplet excitation state. In particular, the T₁ level of [Ir(dppm)₂(acac)] is lower than that of [Ir(mppr-Me)₂(dpm)], which indicates that [Ir(dppm)₂(acac)] has higher emission efficiency than [Ir(mppr-Me)₂(dpm)].

In general, when an atom (a heteroatom) having higher electronegativity than a carbon atom, such as a nitrogen atom, is introduced to constituent atoms of a six-membered aromatic ring such as a benzene ring, the heteroatom attracts π electrons on the ring and the aromatic ring tends to be deficient in electrons. A portion A surrounded by a dotted line in the molecular structure of 2mDBTPDBq-II shown below corresponds to a portion which is deficient in π electrons, and this portion is likely to trap electrons. Heteroaromatic compounds having six-membered rings generally tend to serve as n-type hosts.

Further, in general, when a nitrogen atom, located outside an aromatic ring such as a benzene ring, is bound to the ring, the nitrogen atom donates an unshared electron pair to the benzene ring, whereby electrons become excessive and tend to be released (i.e., holes are likely to be trapped). A portion B surrounded by a dotted line in the molecular structure of PCBNBB shown below corresponds to a portion which is in excess of π electrons, and this portion is likely to release electrons (or trap holes). Aromatic amine compounds generally tend to serve as p-type hosts.

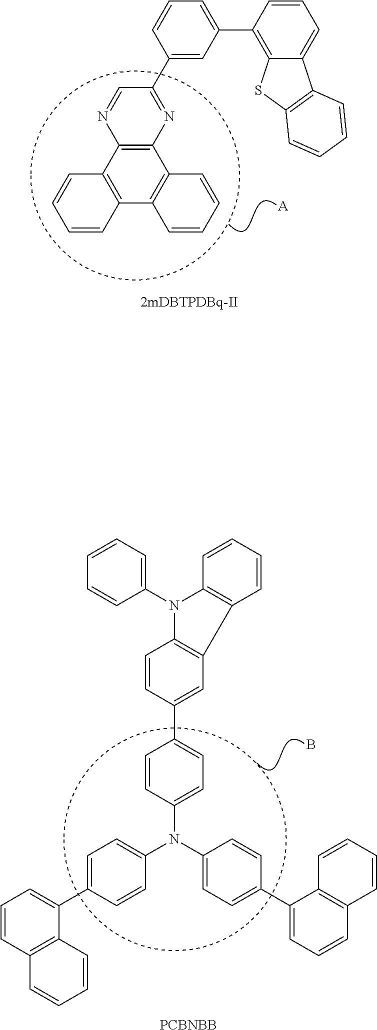

There are relatively large gaps of 0.47 eV between the LUMOs and 0.42 eV between the HOMOs of 2mDBTPDBq-II and PCBNBB. Further, there are relatively large gaps of 0.47 eV between the LUMOs and 0.73 eV between the HOMOs of 2mDBTPDBq-II and PCzPCN1. These gaps serve as barriers to electrons and holes and can prevent the carriers which fail to undergo recombination from penetrating the light-emitting layer. The height of such a barrier is preferably 0.3 eV or more, further preferably 0.4 eV or more.

Whether or not the n-type host and the p-type host form an exciplex can be determined by measuring photoluminescence. When the photoluminescence spectrum of an exciplex overlaps with the absorption spectrum of the guest, it can be said that the energy transfer process due to Förster mechanism is likely to occur.

Described below are examples of an overlap between an absorption spectrum of a guest and a photoluminescence spectrum of each of an n-type host, a p-type host, and a mixed material of the n-type host and the p-type host.

### Structure Example 1

In a structure example 1, 2mDBTPDBq-II was used as an n-type host, PCBNBB was used as a p-type host, and [Ir(mppr-Me)₂(dpm)] was used as a guest.

FIG. 9 shows an absorption spectrum (absorption spectrum A) of [Ir(mppr-Me)₂(dpm)] in a dichloromethane solution of [Ir(mppr-Me)₂(dpm)]. In this example, the absorption spectrum was measured at room temperature with the use of an ultraviolet-visible light spectrophotometer (V-550, manufactured by JASCO Corporation) in a state where the dichloromethane solution was put in a quartz cell.

FIG. 9 also shows a photoluminescence spectrum (emission spectrum 1) of a thin film of 2mDBTPDBq-II, a photoluminescence spectrum (emission spectrum 2) of a thin film of PCBNBB, and a photoluminescence spectrum (emission spectrum 3) of a thin film of a mixed material of 2mDBTPDBq-II and PCBNBB. Note that the weight ratio of 2mDBTPDBq-II to PCBNBB in the thin film of the mixed material was 0.8:0.2.

### Structure Example 2

In a structure example 2, 2mDBTPDBq-II was used as an n-type host, PCzPCN1 was used as a p-type host, and [Ir(dppm)₂(acac)] was used as a guest.

FIG. 10 shows an absorption spectrum (absorption spectrum B) of [Ir(dppm)₂(acac)] in a dichloromethane solution of [Ir(dppm)₂(acac)]. FIG. 10 also shows a photoluminescence spectrum (emission spectrum 4) of a thin film of 2mDBTPDBq-II, a photoluminescence spectrum (emission spectrum 5) of a thin film of PCzPCN1, and a photoluminescence spectrum (emission spectrum 6) of a thin film of a mixed material of 2mDBTPDBq-II and PCzPCN1. Note that the weight ratio of 2mDBTPDBq-II to PCzPCN1 in the thin film of the mixed material was 0.7:0.3.

In each of FIG. 9 and FIG. 10, the horizontal axis represents wavelength (nm), and the vertical axes represent molar absorption coefficient ε (M⁻¹·cm⁻¹) and emission intensity (arbitrary unit).

As can be seen from the absorption spectrum in FIG. 9, [Ir(mppr-Me)₂(dpm)] has a broad absorption band around 500 nm. This absorption band is considered to greatly contribute to light emission.

In FIG. 9, the emission spectrum 3 peaks at a longer wavelength than the emission spectra 1 and 2. In addition, the peak of the emission spectrum 3 is closer to the absorption band than the peaks of the emission spectra 1 and 2.

It is found that the photoluminescence spectrum of the mixed material of 2mDBTPDBq-II and PCBNBB peaks at a longer wavelength than the photoluminescence spectrum of either organic compound alone. This indicates that an exciplex is formed by mixing 2mDBTPDBq-II with PCBNBB. In addition, no emission peak originating from 2mDBTPDBq-II or PCBNBB alone is observed, which means that even if 2mDBTPDBq-II and PCBNBB are separately excited, they immediately form an exciplex.

The peak of the photoluminescence spectrum of the mixed material has a large overlap with the absorption band in the absorption spectrum of [Ir(mppr-Me)₂(dpm)] which is considered to greatly contribute to light emission. This suggests that a light-emitting element including [Ir(mppr-Me)₂(dpm)] and a mixed material of 2mDBTPDBq-II and PCBNBB has high efficiency in energy transfer from an exciplex to a guest. Accordingly, it is suggested that a light-emitting element having high external quantum efficiency can be obtained.

As can be seen from the absorption spectrum in FIG. 10, [Ir(dppm)₂(acac)] has a broad absorption band around 520 nm. This absorption band is considered to greatly contribute to light emission. Note that the peak wavelength of the emission spectrum of [Ir(dppm)₂(acac)] is 592 nm.

In FIG. 10, the emission spectrum 6 peaks at a longer wavelength than the emission spectra 4 and 5. In addition, the peak of the emission spectrum 6 overlaps with the absorption band.

FIG. 10 shows that the photoluminescence spectrum of the mixed material of 2mDBTPDBq-II and PCzPCN1 peaks at a longer wavelength than the photoluminescence spectrum of either organic compound alone. This indicates that an exciplex is formed by mixing 2mDBTPDBq-II with PCzPCN1. In addition, no emission peak originating from 2mDBTPDBq-II or PCzPCN1 alone is observed, which means that even if 2mDBTPDBq-II and PCzPCN1 are separately excited, they immediately form an exciplex.

Further, in the light-emitting element of one embodiment of the present invention, the threshold value of voltage with which an exciplex is formed through carrier recombination (or from a singlet exciton) depends on the energy of a peak of the emission spectrum of the exciplex. When the emission spectrum of the exciplex peaks at 620 nm (2.0 eV), for example, the threshold value of voltage that is needed when the exciplex is formed with electric energy is also approximately 2.0 V. It is preferable that the peak wavelength of the emission spectrum of the exciplex be longer because the threshold value of the voltage can be lowered.

In the structure example 2, the peak wavelength of the emission spectrum of the exciplex is longer than the peak wavelength of the absorption band on the longest wavelength side of the absorption spectrum of the guest. Thus, in a light-emitting element which uses the materials of the structure example 2 for a light-emitting layer, a value of voltage with which an exciplex is formed through carrier recombination is smaller than a value of voltage with which the guest starts to emit light by carrier recombination. In other words, even when voltage that has a value smaller than that of voltage with which the guest starts to emit light is applied to the light-emitting element, recombination current starts to flow in the light-emitting element by exciplex formation through carrier recombination. Therefore, a light-emitting element with lower drive voltage (with more favorable voltage-current characteristics) can be provided. Here, even when the peak wavelength of the emission spectrum of the exciplex is longer than the peak wavelength of the absorption spectrum of the guest, energy can be transferred utilizing the overlap between the emission spectrum of the exciplex and the absorption band located on the longest wavelength side of the absorption spectrum of the guest, which leads to high emission efficiency.

Note that the peak of the emission spectrum of the exciplex is close to the peak of the emission spectrum of the guest, whereby a light-emitting element with low drive voltage and sufficiently high emission efficiency can be obtained. The effect of a reduction in drive voltage is enhanced especially when the peak of the emission spectrum of the exciplex is located in a range from the peak wavelength of the emission spectrum of the guest to a wavelength 30 nm longer than the peak wavelength of the emission spectrum of the guest. Further, relatively high emission efficiency can be maintained when the peak of the emission spectrum of the exciplex is located in a range from the peak wavelength of the emission spectrum of the guest to a wavelength 30 nm shorter than the peak wavelength of the emission spectrum of the guest.

As described above, it was suggested that by the use of [Ir(dppm)₂(acac)] and the mixed material of 2mDBTPDBq-II and PCzPCN1 for a light-emitting element, high emission efficiency (external quantum efficiency) can be achieved with reduced drive voltage, leading to high power efficiency.

### Example 2

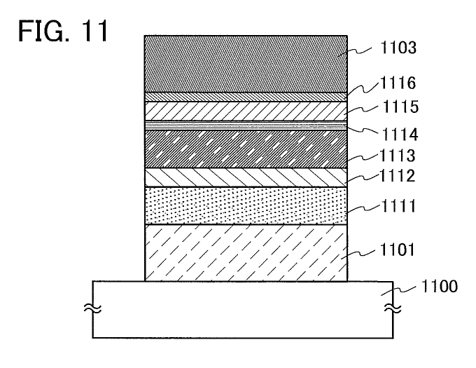

In this example, a light-emitting element of one embodiment of the present invention will be described with reference to FIG. 11. A structural formula of a material used in this example is shown below. Note that the structural formulae of the materials used in the above example are omitted here.

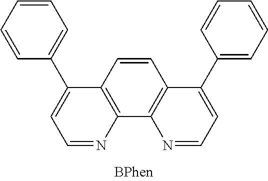 [SMILES: c1ccc(-c2ccnc3c2ccc2c(-c4ccccc4)ccnc23)cc1]

A method for manufacturing a light-emitting element 1 of this example will be described below.

### (Light-Emitting Element 1)

First, a film of ITSO was formed over a glass substrate 1100 by a sputtering method, so that an anode 1101 was formed. Note that the thickness was set to 110 nm and the electrode area was set to 2 mm×2 mm.

Next, as pretreatment for forming the light-emitting element over the glass substrate 1100, UV ozone treatment was performed for 370 seconds after washing of a surface of the substrate with water and baking that was performed at 200° C. for 1 hour.

After that, the substrate was transferred into a vacuum evaporation apparatus where the pressure had been reduced to approximately 10⁻⁴ Pa, and was subjected to vacuum baking at 170° C. for 30 minutes in a heating chamber of the vacuum evaporation apparatus, and then the glass substrate 1100 was cooled down for about 30 minutes.

Next, the glass substrate 1100 provided with the anode 1101 was fixed to a substrate holder in the vacuum evaporation apparatus so that a surface on which the anode 1101 was provided faced downward. The pressure in the vacuum evaporation apparatus was reduced to about 10⁻⁴ Pa. Then, over the anode 1101, PCBNBB and molybdenum(VI) oxide were deposited by co-evaporation to form a hole-injection layer 1111. The thickness was set to 40 nm, and the weight ratio of PCBNBB to molybdenum oxide was adjusted to 4:2 (=PCBNBB: molybdenum oxide).

Next, over the hole-injection layer 1111, a film of PCBNBB was formed to a thickness of 20 nm to faun a first layer 1112 (which corresponds to the layer containing the p-type host).

Furthermore, 2mDBTPDBq-II, PCBNBB, and [Ir(mppr-Me)₂(dpm)] were deposited by co-evaporation to form a light-emitting layer 1113 over the first layer 1112. Here, the weight ratio of 2mDBTPDBq-II to PCBNBB and [Ir(mppr-Me)₂(dpm)] was adjusted to 0.9:0.1:0.05 (=2mDBTPDBq-II: PCBNBB: [Ir(mppr-Me)₂(dpm)]). The thickness of the light-emitting layer 1113 was set to 40 nm.

Next, over the light-emitting layer 1113, a film of 2mDBTPDBq-II was formed to a thickness of 10 nm to form a second layer 1114 (which corresponds to the layer containing the n-type host).

Next, over the second layer 1114, a film of bathophenanthroline (abbreviation: BPhen) was formed to a thickness of 20 nm to form an electron-transport layer 1115.

Further, over the electron-transport layer 1115, a film of lithium fluoride (LiF) was formed by evaporation to a thickness of 1 nm to form an electron-injection layer 1116.

Lastly, an aluminum film was formed by evaporation to a thickness of 200 nm as a cathode 1103. Thus, the light-emitting element 1 of this example was manufactured.

Note that in all the above evaporation steps, evaporation was performed by a resistance heating method.

Table 2 shows an element structure of the light-emitting element 1 obtained as described above.

TABLE 2

| | Hole- | | | | Electron- | Electron- | |
|---|---|---|---|---|---|---|---|
| | transport | First | | | transport | injection | |
| Anode | Layer | Layer | Light-emitting Layer | Second Layer | Layer | Layer | Cathode |
| ITSO | PCBNBB:MoOₓ | PCBNBB | 2mDBTPDBq-II:PCBNBB: | 2mDBTPDBq-II | BPhen | LiF | Al |
| 110 nm | (=4:2) | 20 nm | [Ir(mppr-Me)₂(dpm)] | 10 nm | 20 nm | 1 nm | 200 nm |
| | 40 nm | | (=0.9:0.1:0.05) | | | | |
| | | | 40 nm | | | | |

In a glove box containing a nitrogen atmosphere, the light-emitting element 1 was sealed so as not to be exposed to air. Then, operation characteristics of the light-emitting element were measured. Note that the measurement was carried out at room temperature (in the atmosphere kept at 25° C.).

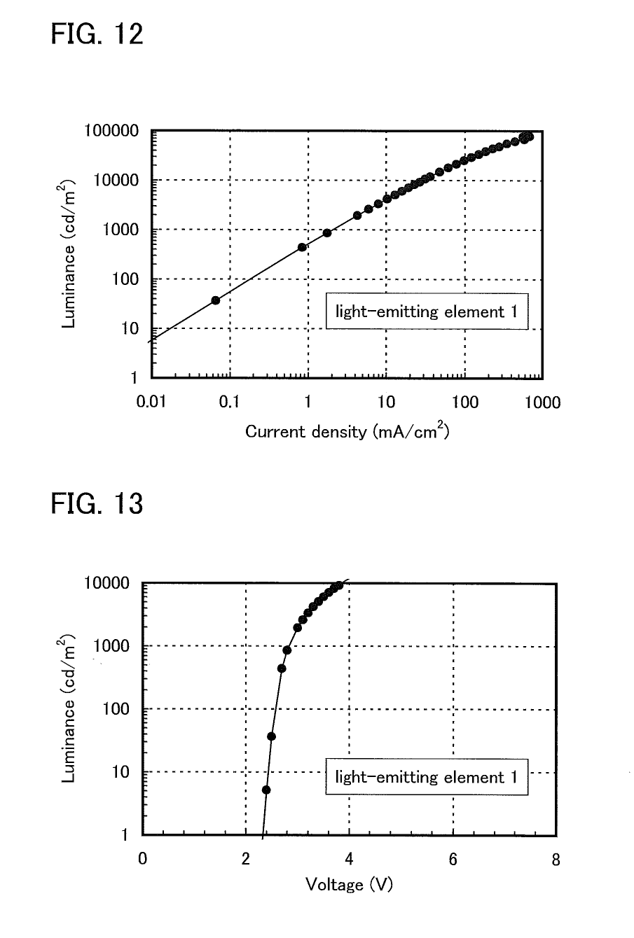

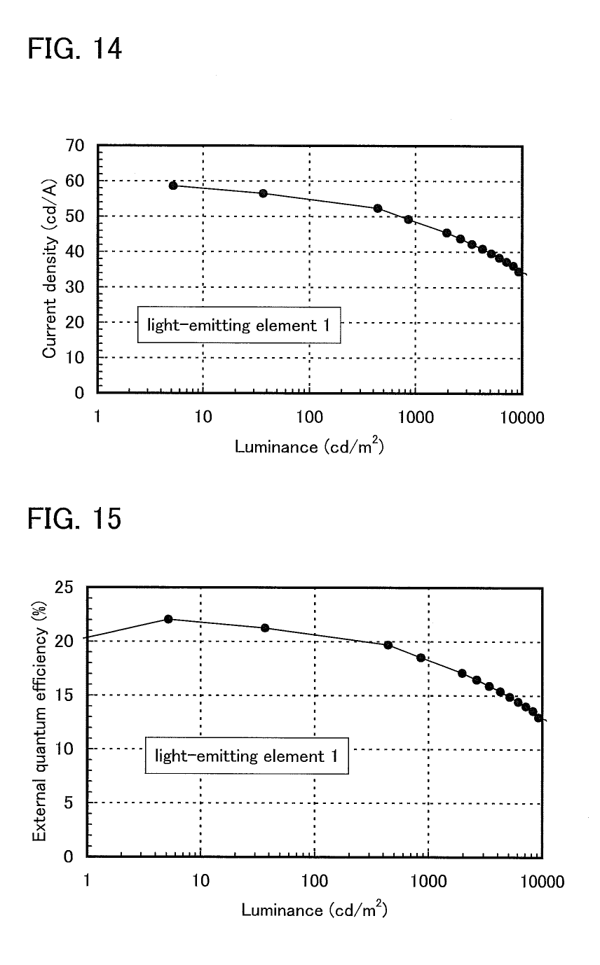

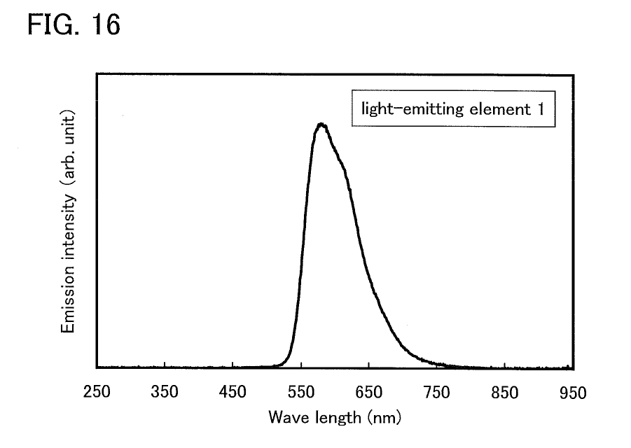

FIG. 12 shows current density-luminance characteristics of the light-emitting element 1. In FIG. 12, the horizontal axis represents current density (mA/cm²), and the vertical axis represents luminance (cd/m²). FIG. 13 shows voltage-luminance characteristics thereof. In FIG. 13, the horizontal axis represents voltage (V), and the vertical axis represents luminance (cd/m²). FIG. 14 shows luminance-current efficiency characteristics thereof. In FIG. 14, the horizontal axis represents luminance (cd/m²), and the vertical axis represents current efficiency (cd/A). FIG. 15 shows luminance-external quantum efficiency characteristics thereof. In FIG. 15, the horizontal axis represents luminance (cd/m²), and the vertical axis represents external quantum efficiency (%).

Further, Table 3 shows the voltage (V), current density (mA/cm²), CIE chromaticity coordinates (x, y), current efficiency (cd/A), power efficiency (lm/W), and external quantum efficiency (%) of the light-emitting element 1 at a luminance of 1000 cd/m².

TABLE 3

| | | | | | External |
|---|---|---|---|---|---|
| | Current | | Current | Power | Quantum |
| Voltage | Density | Chromaticity | Efficiency | Efficiency | Efficiency |
| (V) | (mA/cm²) | (x, y) | (cd/A) | (lm/W) | (%) |
| 2.8 | 1.75 | (0.53, 0.46) | 49 | 55 | 19 |

FIG. 16 shows an emission spectrum of the light-emitting element 1 which was obtained by applying a current of 0.1 mA. In FIG. 16, the horizontal axis represents wavelength (nm), and the vertical axis represents emission intensity (arbitrary unit). As shown in Table 3, the CIE chromaticity coordinates of the light-emitting element 1 at a luminance of 1000 cd/m² were (x, y)=(0.53, 0.46). These results show that orange light emission originating from [Ir(mppr-Me)₂(dpm)] was obtained from the light-emitting element 1.

As can be seen from Table 3 and FIGS. 12 to 15, the light-emitting element 1 has high current efficiency, high power efficiency, and high external quantum efficiency.

In the light-emitting element 1 of this example, 2mDBTPDBq-II, PCBNBB, and [Ir(mppr-Me)₂(dpm)] described in Example 1 are used for the light-emitting layer. As described in Example 1, the photoluminescence spectrum of the mixed material of 2mDBTPDBq-II and PCBNBB (the photoluminescence spectrum of an exciplex) has a larger overlap with the absorption spectrum of [Ir(mppr-Me)₂(dpm)] than the photoluminescence spectrum of 2mDBTPDBq-II or PCBNBB alone. The light-emitting element 1 of this example is considered to have high energy transfer efficiency because it transfers energy by utilizing the overlap, and therefore have high external quantum efficiency.

The above results show that an element having high external quantum efficiency can be obtained by application of one embodiment of the present invention.

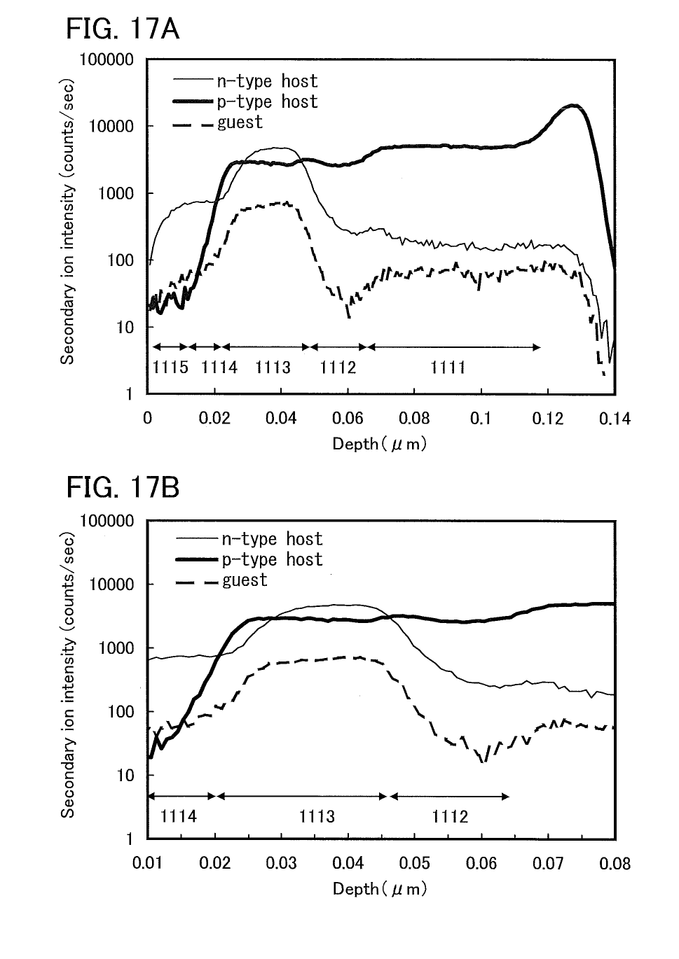

Next, the light-emitting element 1 was analyzed by a ToF-SIMS using a gas cluster ion beam (GCIB). The analysis was performed in the depth direction. Specifically, measurement was performed from a surface from which the aluminum and LiF were removed by peeling (i.e., from the BPhen side). Here, bismuth (Bi) was used for a primary ion source, an argon (Ar) gas was used for gas cluster ions, and acceleration voltage was 25 keV. Results of the measurement by a ToF-SIMS are shown in FIGS. 17A and 17B. In each of FIGS. 17A and 17B, the horizontal axis represents the depth (m) of location of the measurement and the vertical axis represents secondary ion intensity (counts/sec).

The secondary ion intensity of the n-type host (2mDBTPDBq-II) was compared between the first layer 1112, the light-emitting layer 1113, and the second layer 1114. FIG. 17B shows that the light-emitting layer 1113 has the highest secondary ion intensity of the n-type host, the second layer 1114 has the second-highest secondary ion intensity of the n-type host, and the first layer 1112 has the lowest secondary ion intensity of the n-type host.

In a similar manner, the secondary ion intensity of the p-type host (PCBNBB) was compared between the first layer 1112, the light-emitting layer 1113, and the second layer 1114. FIG. 17B shows that the first layer 1112 and the light-emitting layer 1113 have secondary ion intensities of the p-type host which are close to each other, and the second layer 1114 has the lowest secondary ion intensity of the p-type host.

Further, the guest ([Ir(mppr-Me)₂(dpm)]) has the highest secondary ion intensity in the light-emitting layer 1113.

In the light-emitting element 1, in spite of the fact that the p-type host exists alone in the first layer 1112 and the p-type host accounts for only about 10% of the light-emitting layer 1113, the secondary ion intensity of the p-type host of the light-emitting layer 1113 is as high as that of the p-type host of the first layer 1112. Moreover, in the light-emitting element 1, in spite of the fact that the light-emitting layer 1113 contains not only the n-type host but also the p-type host and the guest unlike the second layer 1114 in which the n-type host exists alone, the secondary ion intensity of the n-type host of the light-emitting layer 1113 is higher than that of the n-type host of the second layer 1114. The above proves that secondary ions tend to be detected more easily from a layer (the light-emitting layer 1113) in which a p-type host and an n-type host are mixed than from a layer (the first layer 1112 or the second layer 1114) in which the p-type host or the n-type host exists alone. As already described above, in analysis by a ToF-SIMS, it can be said that when a material contained in a layer has high secondary ion intensity, the molecules of the material are not readily decomposed at the time of ionization. It is thus suggested that even in the case where current flows into the light-emitting element of one embodiment of the present invention, the molecules of the p-type host or the n-type host contained in the light-emitting layer are less likely to be decomposed than the molecules of the p-type host or the n-type host existing alone. Therefore, by application of one embodiment of the present invention, a light-emitting element with a long lifetime can be obtained.

### Example 3

In this example, a light-emitting element of one embodiment of the present invention will be described with reference to FIG. 11. Structural formulae of materials used in this example are shown below. Note that the structural formulae of the materials used in the above examples are omitted here.

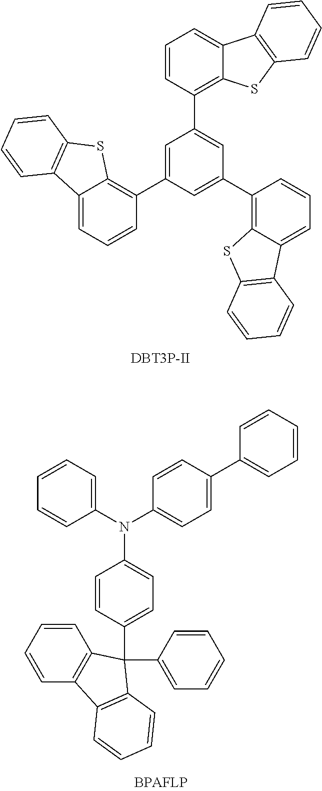 [SMILES: c1ccc2c(c1)sc1c(-c3cc(-c4cccc5c4sc4ccccc45)cc(-c4cccc5c4sc4ccccc45)c3)cccc12 ; "DBT3P-II" ; c1ccc(-c2ccc(N(c3ccccc3)c3ccc(C4(c5ccccc5)c5ccccc5-c5ccccc54)cc3)cc2)cc1]

A method for manufacturing a light-emitting element 2 of this example will be described below.

### (Light-Emitting Element 2)

First, a film of ITSO was formed over the glass substrate 1100 by a sputtering method, so that the anode 1101 was formed. Note that the thickness was set to 110 nm and the electrode area was set to 2 mm×2 mm.

Next, as pretreatment for forming the light-emitting element over the glass substrate 1100, UV ozone treatment was performed for 370 seconds after washing of a surface of the substrate with water and baking that was performed at 200° C. for 1 hour.

After that, the substrate was transferred into a vacuum evaporation apparatus where the pressure had been reduced to approximately 10⁻⁴ Pa, and was subjected to vacuum baking at 170° C. for 30 minutes in a heating chamber of the vacuum evaporation apparatus, and then the glass substrate 1100 was cooled down for about 30 minutes.

Next, the glass substrate 1100 provided with the anode 1101 was fixed to a substrate holder in the vacuum evaporation apparatus so that a surface on which the anode 1101 was provided faced downward. The pressure in the vacuum evaporation apparatus was reduced to about 10⁻⁴ Pa. Then, over the anode 1101, 4,4′, 4″-(1,3,5-benzenetriyl)tri(dibenzothiophene) (abbreviation: DBT3P-II) and molybdenum(VI) oxide were deposited by co-evaporation to form the hole-injection layer 1111. The thickness was set to 40 nm, and the weight ratio of DBT3P-II to molybdenum oxide was adjusted to 4:2 (=DBT3P-II: molybdenum oxide).

Next, over the hole-injection layer 1111, 4-phenyl-4′-(9-phenylfluoren-9-yl)triphenylamine (abbreviation: BPAFLP) and PCzPCN1 were deposited by co-evaporation to form the first layer 1112 (which corresponds to the layer containing the p-type host). The thickness was 20 nm and the weight ratio of BPAFLP to PCzPCN1 was adjusted to 0.5:0.5.

Furthermore, 2mDBTPDBq-II, PCzPCN1, and [Ir(dppm)₂(acac)] were deposited by co-evaporation to form the light-emitting layer 1113 over the first layer 1112. Here, a 20-nm-thick layer deposited with a weight ratio of 2mDBTPDBq-II to PCzPCN1 and [Ir(dppm)₂(acac)] adjusted to 0.7:0.3:0.06 (=2mDBTPDBq-II: PCzPCN1: [Ir(dppm)₂(acac)]) and a 20-nm-thick layer deposited with a weight ratio of 2mDBTPDBq-II to PCzPCN1 and [Ir(dppm)₂(acac)] adjusted to 0.8:0.2:0.05 (=2mDBTPDBq-II: PCzPCN1: [Ir(dppm)₂(acac)]) were stacked.

Next, over the light-emitting layer 1113, a film of 2mDBTPDBq-II was formed to a thickness of 10 nm to form the second layer 1114 (which corresponds to the layer containing the n-type host).

Next, over the second layer 1114, a film of BPhen was formed to a thickness of 20 nm to form the electron-transport layer 1115.

Further, over the electron-transport layer 1115, a film of LiF was formed by evaporation to a thickness of 1 nm to form the electron-injection layer 1116.

Lastly, an aluminum film was formed by evaporation to a thickness of 200 nm as the cathode 1103. Thus, the light-emitting element 2 of this example was manufactured.

Note that in all the above evaporation steps, evaporation was performed by a resistance heating method.

Table 4 shows an element structure of the light-emitting element 2 obtained as described above.

TABLE 4

| | Hole- | | | | Electron- | Electron- | |
|---|---|---|---|---|---|---|---|
| | injection | | | | transport | injection | |
| Anode | Layer | First Layer | Light-emitting Layer | Second Layer | Layer | Layer | Cathode |
| ITSO | DBT3P-II:MoOₓ | BPAFLP:PCzPCN1 | 2mDBTPDBq-II:PCzPCN1: | 2mDBTPDBq-II | BPhen | LiF | Al |
| 110 nm | (=4:2) | (=0.5:0.5) | [Ir(dppm)₂(acac)] | 10 nm | 20 nm | 1 nm | 200 nm |

| | | | |
|---|---|---|---|
| 40 nm | 20 nm | (=0.7:0.3:0.06) | (=0.8:0.2:0.05) |
| | | 20 nm | 20 nm |

In a glove box containing a nitrogen atmosphere, the light-emitting element 2 was sealed so as not to be exposed to air. Then, operation characteristics of the light-emitting element were measured. Note that the measurement was carried out at room temperature (in the atmosphere kept at 25° C.).

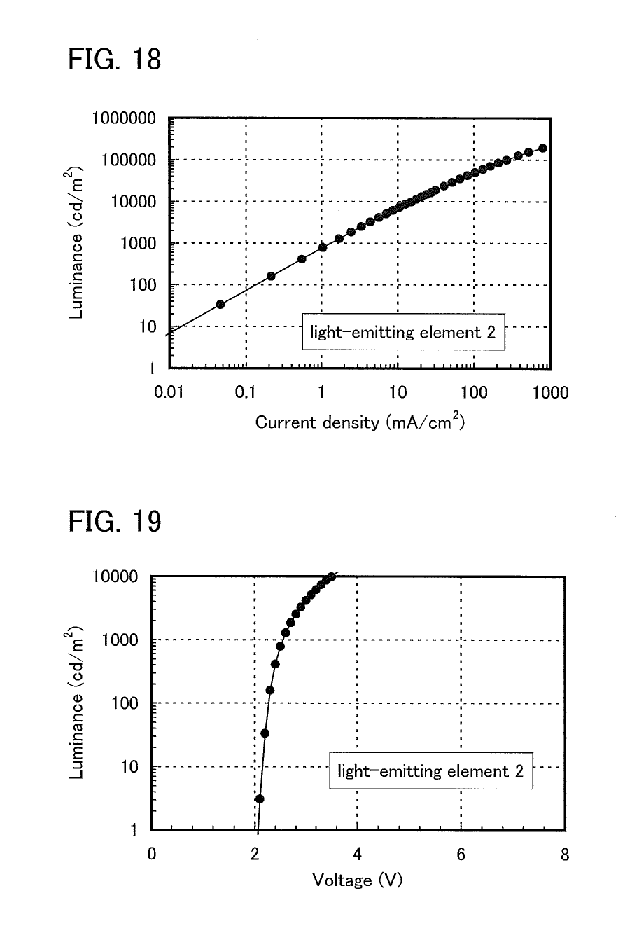

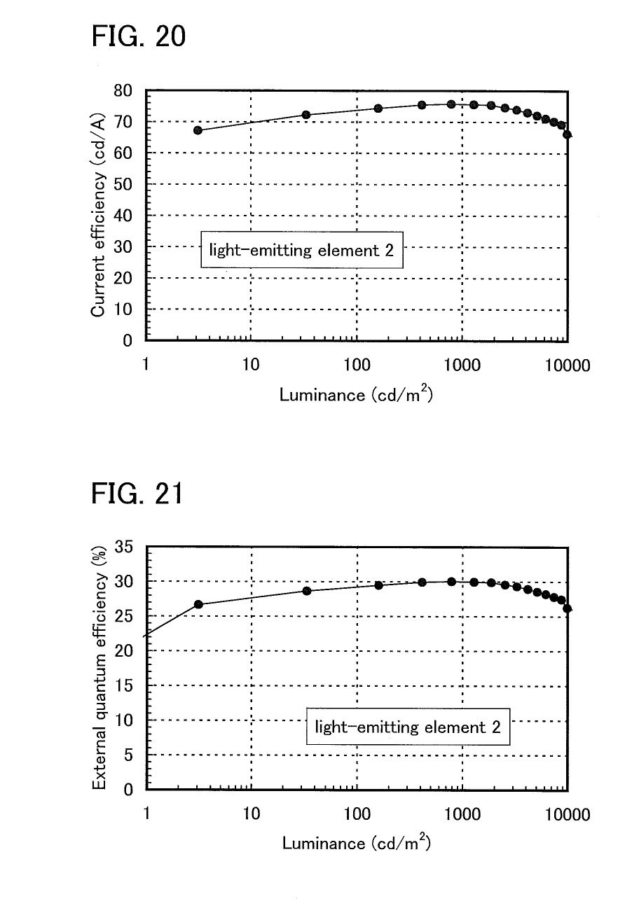

FIG. 18 shows current density-luminance characteristics of the light-emitting element 2. In FIG. 18, the horizontal axis represents current density (mA/cm²), and the vertical axis represents luminance (cd/m²). FIG. 19 shows voltage-luminance characteristics thereof. In FIG. 19, the horizontal axis represents voltage (V), and the vertical axis represents luminance (cd/m²). FIG. 20 shows luminance-current efficiency characteristics thereof. In FIG. 20, the horizontal axis represents luminance (cd/m²), and the vertical axis represents current efficiency (cd/A). FIG. 21 shows luminance-external quantum efficiency characteristics thereof. In FIG. 21, the horizontal axis represents luminance (cd/m²), and the vertical axis represents external quantum efficiency (%).

Further, Table 5 shows the voltage (V), current density (mA/cm²), CIE chromaticity coordinates (x, y), current efficiency (cd/A), power efficiency (lm/W), and external quantum efficiency (%) of the light-emitting element 2 at a luminance of 1000 cd/m².

TABLE 5

| | | | | | External |
|---|---|---|---|---|---|
| | Current | | Current | Power | Quantum |
| Voltage | Density | Chromaticity | Efficirncy | Efficiency | Efficiency |
| (V) | (mA/cm²) | (x, y) | (cd/A) | (lm/W) | (%) |
| 2.5 | 1.04 | (0.57, 0.43) | 76 | 95 | 30 |

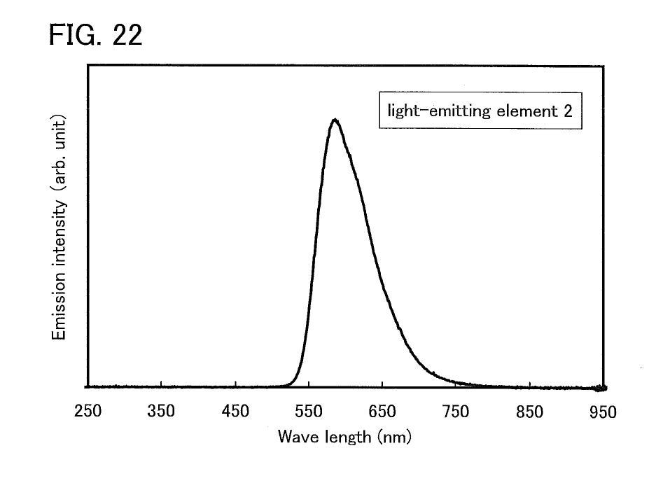

FIG. 22 shows an emission spectrum of the light-emitting element 2 which was obtained by applying a current of 0.1 mA. In FIG. 22, the horizontal axis represents wavelength (nm), and the vertical axis represents emission intensity (arbitrary unit). As shown in Table 5, the CIE chromaticity coordinates of the light-emitting element 2 at a luminance of 1000 cd/m² were (x, y)=(0.57, 0.43). These results show that orange light emission originating from [Ir(dppm)₂(acac)] was obtained from the light-emitting element 2.

As can be seen from Table 5 and FIGS. 18 to 21, the light-emitting element 2 has high current efficiency, high power efficiency, and high external quantum efficiency.

In the light-emitting element 2 of this example, 2mDBTPDBq-II, PCzPCN1, and [Ir(dppm)₂(acac)] described in Example 1 are used for the light-emitting layer. As described in Example 1, the photoluminescence spectrum of the mixed material of 2mDBTPDBq-II and PCzPCN1 (the photoluminescence spectrum of an exciplex) has a larger overlap with the absorption spectrum of [Ir(dppm)₂(acac)] than the photoluminescence spectrum of 2mDBTPDBq-II or PCzPCN1 alone. The light-emitting element 2 of this example is considered to have high energy transfer efficiency because it transfers energy by utilizing the overlap, and therefore have high external quantum efficiency.

The above results show that an element having high external quantum efficiency can be obtained by application of one embodiment of the present invention.

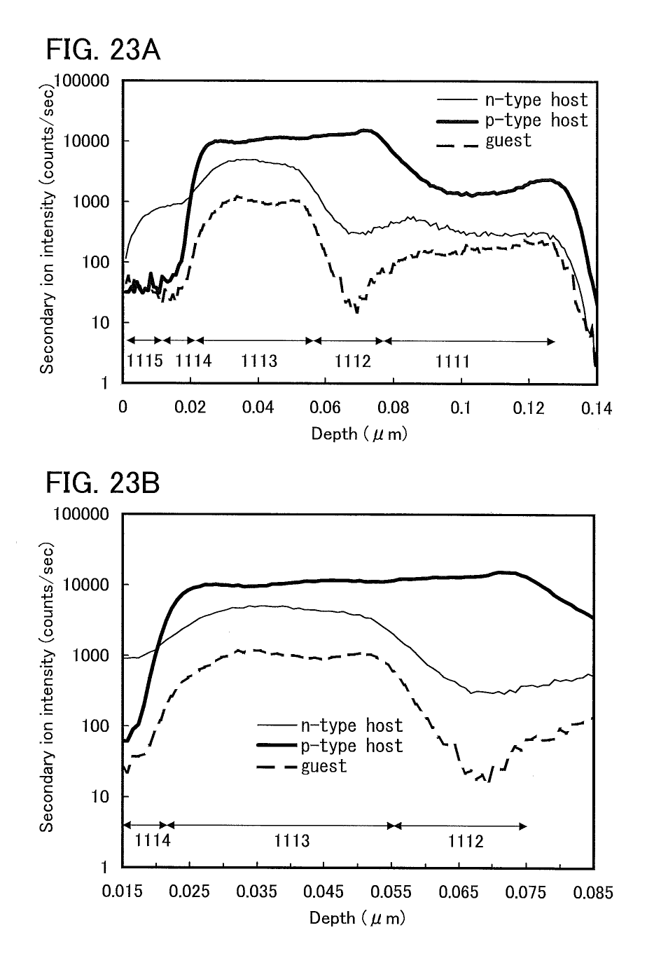

Next, the light-emitting element 2 was analyzed by a ToF-SIMS using a gas cluster ion beam (GCIB). A method and conditions of the measurement were similar to those in Example 2. FIGS. 23A and 23B show data obtained by a ToF-SIMS. In each of FIGS. 23A and 23B, the horizontal axis represents the depth (μm) of location of the measurement and the vertical axis represents secondary ion intensity (counts/sec).

The secondary ion intensity of the n-type host (2mDBTPDBq-II) was compared between the first layer 1112, the light-emitting layer 1113, and the second layer 1114. FIG. 23B shows that the light-emitting layer 1113 has the highest secondary ion intensity of the n-type host, the second layer 1114 has the second-highest secondary ion intensity of the n-type host, and the first layer 1112 has the lowest secondary ion intensity of the n-type host.

In a similar manner, the secondary ion intensity of the p-type host (PCzPCN1) was compared between the first layer 1112, the light-emitting layer 1113, and the second layer 1114. FIG. 23B shows that the first layer 1112 and the light-emitting layer 1113 have secondary ion intensities of the p-type host which are close to each other, and the second layer 1114 has the lowest secondary ion intensity of the p-type host.

Further, the guest ([Ir(dppm)₂(acac)]) has the highest secondary ion intensity in the light-emitting layer 1113.

In the light-emitting element 2, in spite of the fact that the content of the p-type host in the light-emitting layer 1113 is lower than that of the p-type host in the first layer 1112, the secondary ion intensity of the p-type host of the light-emitting layer 1113 is as high as that of the p-type host of the first layer 1112. Moreover, in the light-emitting element 2, in spite of the fact that the light-emitting layer 1113 contains not only the n-type host but also the p-type host and the guest unlike the second layer 1114 in which the n-type host exists alone, the secondary ion intensity of the n-type host of the light-emitting layer 1113 is higher than that of the n-type host of the second layer 1114. The above proves that secondary ions tend to be detected more easily from a layer (the light-emitting layer 1113) in which a p-type host and an n-type host are mixed than from a layer (here, the second layer 1114) in which the p-type host or the n-type host exists alone. As already described above, in analysis by a ToF-SIMS, it can be said that when a material contained in a layer has high secondary ion intensity, the molecules of the material are not readily decomposed at the time of ionization. It is thus suggested that even in the case where current flows into the light-emitting element of one embodiment of the present invention, the molecules of the p-type host or the n-type host contained in the light-emitting layer are less likely to be decomposed than the molecules of the p-type host or the n-type host existing alone. Therefore, by application of one embodiment of the present invention, a light-emitting element with a long lifetime can be obtained.

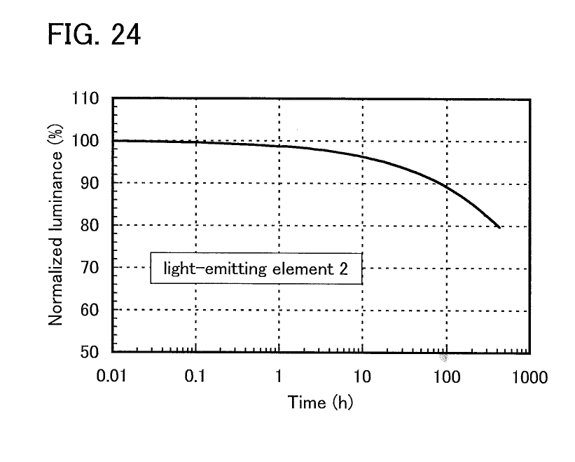

Next, the light-emitting element 2 was subjected to a reliability test. Results of the reliability test are shown in FIG. 24. In FIG. 24, the vertical axis represents normalized luminance (%) with an initial luminance of 100%, and the horizontal axis represents driving time (h) of the element.

In the reliability test, the light-emitting element 2 was driven under the conditions where the initial luminance was set to 5000 cd/m² and the current density was constant.

The luminance of the light-emitting element 2 after 430 hours was 80% of the initial luminance. The results indicate that the light-emitting element 2 has a long lifetime.

The above results show that an element having high emission efficiency and high reliability can be obtained by application of one embodiment of the present invention.

This application is based on Japanese Patent Application serial no. 2012-208661 filed with Japan Patent Office on Sep. 21, 2012, the entire contents of which are hereby incorporated by reference.

What is claimed is:

1. A light-emitting element comprising:
a first electrode;
a light-emitting layer comprising a phosphorescent compound and an organic compound over the first electrode;
a first layer comprising the organic compound over the light-emitting layer; and
a second electrode over the first layer,
wherein, in the light-emitting layer, a concentration of the organic compound is higher than a concentration of the phosphorescent compound, and
wherein secondary ion intensity of the organic compound detected by a time-of-flight secondary ion mass spectrometer is higher in the light-emitting layer than in the first layer.

2. The light-emitting element according to claim 1, wherein the organic compound has an electron-transport property.

3. The light-emitting element according to claim 1, wherein the organic compound is a nitrogen-containing heteroaromatic compound.

4. The light-emitting element according to claim 1, wherein the organic compound is a six-membered heteroaromatic compound.

5. The light-emitting element according to claim 1, wherein the phosphorescent compound is an organometallic complex.

6. A light-emitting element comprising:
a first electrode;
a first layer comprising a first organic compound over the first electrode;
a light-emitting layer comprising a phosphorescent compound, the first organic compound, and a second organic compound over the first layer;
a second layer comprising the second organic compound over the light-emitting layer; and
a second electrode over the second layer,
wherein, in the light-emitting layer, a concentration of the second organic compound is higher than a concentration of the first organic compound and a concentration of the phosphorescent compound, and
wherein secondary ion intensity of the second organic compound detected by a time-of-flight secondary ion mass spectrometer is higher in the light-emitting layer than in the second layer.

7. The light-emitting element according to claim 6,
wherein the first organic compound has a hole-transport property, and
wherein the second organic compound has an electron-transport property.

8. The light-emitting element according to claim 6, wherein the first organic compound is an aromatic amine compound.

9. The light-emitting element according to claim 6, wherein the second organic compound is a nitrogen-containing heteroaromatic compound.

10. The light-emitting element according to claim 6, wherein the second organic compound is a six-membered heteroaromatic compound.

11. The light-emitting element according to claim 6, wherein the phosphorescent compound is an organometallic complex.

12. The light-emitting element according to claim 6, wherein the first organic compound and the second organic compound form an exciplex in the light-emitting layer.

13. A light-emitting element comprising:
a first layer comprising a first organic compound;
a light-emitting layer comprising a phosphorescent compound, the first organic compound, and a second organic compound over and in contact with the first layer; and
a second layer comprising the second organic compound over and in contact with the light-emitting layer,
wherein the first organic compound has a hole-transport property,
wherein the second organic compound has an electron-transport property,
wherein an energy difference between a LUMO level of the phosphorescent compound and a LUMO level of the second organic compound is equal to or less than 0.3 eV, and
wherein secondary ion intensity of the second organic compound detected by a time-of-flight secondary ion mass spectrometer is higher in the light-emitting layer than in the second layer.

14. The light-emitting element according to claim 13,
wherein the light-emitting layer comprises a first region and a second region,
wherein, in the first region, a concentration of the second organic compound is higher than a concentration of the first organic compound, and
wherein, in the second region, a concentration of the second organic compound is lower than a concentration of the first organic compound.

15. The light-emitting element according to claim 13, wherein the first organic compound is an aromatic amine compound.

16. The light-emitting element according to claim 13, wherein the second organic compound is a nitrogen-containing heteroaromatic compound.

17. The light-emitting element according to claim 13, wherein the second organic compound is a six-membered heteroaromatic compound.

18. The light-emitting element according to claim 13, wherein the phosphorescent compound is an organometallic complex.

19. The light-emitting element according to claim 13, wherein the first organic compound and the second organic compound form an exciplex in the light-emitting layer.

20. A lighting device comprising the light-emitting element according to claim 13.
